(19) United States
(12) Patent Application Publication
(10) Pub. No.: US 2016/0247729 A1
(43) Pub. Date: Aug. 25, 2016

(54) Semiconductor Device and Method of Manufacturing the Same

(71) Applicant: RENESAS ELECTONICS CORPORATION, Kawasaki-shi, Kanagawa (JP)

(72) Inventor: Keiji SAKAMOTO, Kanasaki-shi, Kanagawa (JP)

(21) Appl. No.: 14/381,433

(22) PCT Filed: Dec. 5, 2013
(86) PCT No.: PCT/JP2013/082727

§ 371 Date: Aug. 27, 2014

(51) Int. Cl. H01L 21/8238; H01L 23/532; H01L 27/092

(52) U.S. Cl. CPC H01L 21/823842; H01L 27/092; H01L 21/823878; H01L 21/823835; H01L 21/823871; H01L 23/53209

(57) ABSTRACT

A semiconductor device includes: a first silicon section G1 which contains a p-type impurity and is a gate electrode G of a p-channel type MISFET 1P; a second silicon section G2 which contains an n-type impurity and is a gate electrode G of an n-channel type MISFET 2N; and an insulation film IF1 which is interposed between the first silicon section G1 and the second silicon section G2. Then, a silicide film is formed continuously on surfaces of the first silicon section G1, the insulation film IF1 and the second silicon section G2, and the first silicon section G1 and the second silicon section G2 are electrically connected to each other by the silicide film SIL. Impurity inter-diffusion can be prevented by the insulation film IF1.

### TECHNICAL FIELD

The present invention relates to a semiconductor device and a method of manufacturing the same, and can be used suitably for a semiconductor device and a method of manufacturing the same which has a so-called complementary-type MISFET having a dual gate structure in which, for example, a gate electrode of an n-channel type MISFET and a gate electrode of a p-channel type MISFET are formed of silicon films having different conductivity types from each other.

### BACKGROUND ART

In a semiconductor layer having a complementary-type MISFET in recent years, a dual gate structure is adopted widely. As for the dual gate structure, a gate electrode (n-type gate electrode) of an n-channel type MISFET is formed of an n-type polycrystalline silicon film, and a gate electrode (p-type gate electrode) of a p-channel type MISFET is configured of a p-type polycrystalline silicon film. In the dual gate structure, since a short channel effect can be suppressed by particularly providing a surface channel structure to the p-channel type MISFET, microfabrication of the p-channel type MISFET can be achieved.

However, in the complementary-type MISFET having the dual gate structure, problems resulting from impurity inter-diffusion between an impurity in the p-type gate electrode and an impurity in the n-type gate electrode have conventionally become obvious, and a patent related to the problem has been applied.

Japanese Patent Application Laid-open Publication No. 2008-288402 (Patent Document 1) discloses a structure in which a width of a boundary portion between the p-type gate electrode and the n-type gate electrode is narrower (thinner) than a width of the gate electrode portion by providing a cutout to the boundary portion between the p-type gate electrode and the n-type gate electrode when seen in a plan view in order to suppress the diffusion of the impurity in one gate electrode to the other gate electrode. In addition, the document discloses a technique of reducing a contact resistance between a gate electrode and a contact plug by forming a concave portion on an upper surface of the gate electrode.

Japanese Patent Application Laid-open Publication No. 2002-76139 (Patent Document 2) discloses a structure in which a WSi2 layer is removed in a boundary region between a polycrystalline silicon film containing a p-type impurity and a polycrystalline silicon film containing an n-type impurity in order to prevent the impurity inter-diffusion via the WSi2 layer.

### PRIOR ART DOCUMENTS

### Patent Documents

Patent Document 1: Japanese Patent Application Laid-open Publication No. 2008-288402
Patent Document 2: Japanese Patent Application Laid-open Publication No. 2002-76139

### SUMMARY OF THE INVENTION

### Problems to be Solved by the Invention

In the semiconductor device (semiconductor chip) which has the complementary-type MISFET having the dual gate structure in recent years, there are many portions each having dimensions of a p-type and an n-type gate electrodes in a gate length direction which are the minimum processing dimension in a process in order to achieve the microfabrication and high integration, and therefore, it is difficult to provide the cutout to the boundary portion between the p-type gate electrode and the n-type gate electrode when seen in the plan view.

In addition, it is required to form the width of the boundary region (isolation region) between the p-channel type MISFET and the n-channel type MISFET which configure the complementary-type MISFET so as to be narrower than that of a conventional structure. Therefore, depletion of the gate electrode is caused by the impurity inter-diffusion between the impurity in the p-type gate electrode and the impurity in the n-type gate electrode, and a problem of increase in a threshold voltage has become more obvious.

In the complementary-type MISFET having the dual gate structure, it is desired to provide a semiconductor device which suppresses the increase in the threshold value so as to increase reliability.

Other problems and novel characteristics will be apparent from the description of the present specification and the accompanying drawings.

### Means for Solving the Problems

According to one embodiment, a semiconductor device includes: a first silicon section which has a p-type impurity and is a gate electrode of a p-channel type MISFET; a second silicon section which has an n-type impurity and is a gate electrode of an n-channel type MISFET; and an insulation film which is interposed between the first silicon section and the second silicon section. Then, a silicide film is formed continuously on each surface of the first silicon section, the insulation film and the second silicon section, and the first silicon section and the second silicon section are electrically connected to each other by the silicide film.

### Effects of the Invention

According to one embodiment, a semiconductor device having high reliability can be provided.

### BRIEF DESCRIPTIONS OF THE DRAWINGS

FIG. 1 is a circuit diagram illustrating an inverter circuit according to one embodiment;

FIG. 2 is a plan view illustrating a layout configuration example of the inverter circuit according to one embodiment;

FIG. 3 is a cross-sectional view of a principal part of a semiconductor device according to one embodiment;

FIG. 4 is a cross-sectional view of a principal part illustrating a step of manufacturing the semiconductor device according to one embodiment;

FIG. 5 is a cross-sectional view of a principal part illustrating a step of manufacturing the semiconductor device, continued from FIG. 4;

FIG. 6 is a plane view of a principal part in the step of manufacturing the semiconductor device, as the same as in FIG. 5;

FIG. 7 is a cross-sectional view of a principal part illustrating the manufacturing process of the semiconductor device, continued from FIG. 5;

FIG. 8 is a cross-sectional view of a principal part illustrating a step of manufacturing the semiconductor device, continued from FIG. 7;

FIG. 9 is a cross-sectional view of a principal part illustrating a step of manufacturing the semiconductor device, continued from FIG. 8;

FIG. 10 is a cross-sectional view of a principal part illustrating a step of manufacturing the semiconductor device, continued from FIG. 9;

FIG. 11 is a cross-sectional view of a principal part illustrating a step of manufacturing the semiconductor device, continued from FIG. 10;

FIG. 12 is a plane view of a principal part in the step of manufacturing the semiconductor device, as the same as in FIG. 11;

FIG. 13 is a cross-sectional view of a principal part illustrating a step of manufacturing the semiconductor device, continued from FIG. 11;

FIG. 14 is a cross-sectional view of a principal part illustrating a step of manufacturing the semiconductor device, continued from FIG. 13;

FIG. 15 is a cross-sectional view of a principal part illustrating a step of manufacturing the semiconductor device, continued from FIG. 14;

FIG. 16 is a cross-sectional view of a principal part illustrating a step of manufacturing the semiconductor device, continued from FIG. 15;

FIG. 17 is a cross-sectional view of a principal part illustrating a step of manufacturing the semiconductor device, continued from FIG. 16;

FIG. 18 is a cross-sectional view of a principal part of a semiconductor device according to a second embodiment;

FIG. 19 is a cross-sectional view of a principal part of a semiconductor device according to a third embodiment;

FIG. 20 is a cross-sectional view of a principal part illustrating a step of manufacturing the semiconductor device according to the third embodiment;

FIG. 21 is a cross-sectional view of a principal part illustrating a step of manufacturing the semiconductor device, continued from FIG. 20;

FIG. 22 is a cross-sectional view of a principal part illustrating a step of manufacturing the semiconductor device, continued from FIG. 21;

FIG. 23 is a cross-sectional view of a principal part illustrating a step of manufacturing the semiconductor device, continued from FIG. 22;

FIG. 24 is a cross-sectional view of a principal part illustrating a step of manufacturing the semiconductor device, continued from FIG. 23;

FIG. 25 is a cross-sectional view of a principal part illustrating a step of manufacturing the semiconductor device, continued from FIG. 24; and

FIG. 26 is a cross-sectional view of a principal part illustrating a step of manufacturing the semiconductor device, continued from FIG. 25.

### BEST MODE FOR PERFORMING THE INVENTION

Hereafter, an embodiment of the present invention will be described in detail based on drawings. Note that the same components are denoted by the same reference symbols in principle throughout all drawings for describing the embodiments, and the repetitive description thereof will be omitted.

### First Embodiment

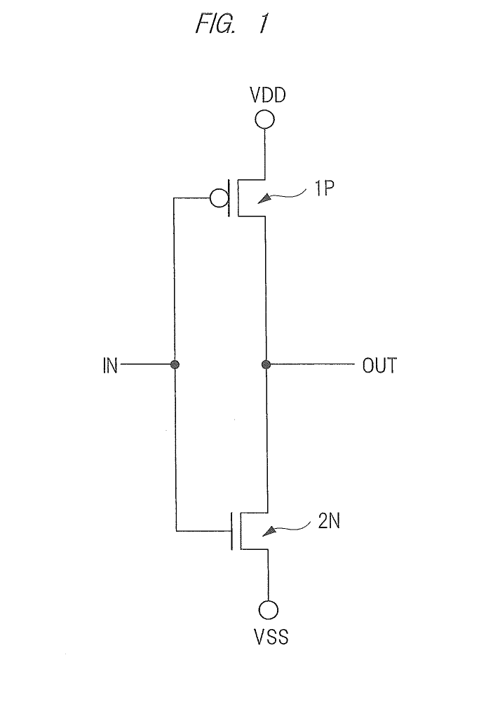

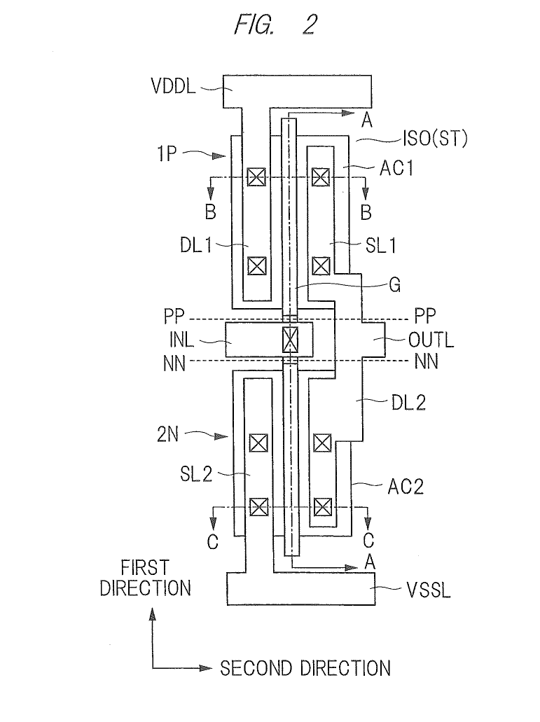

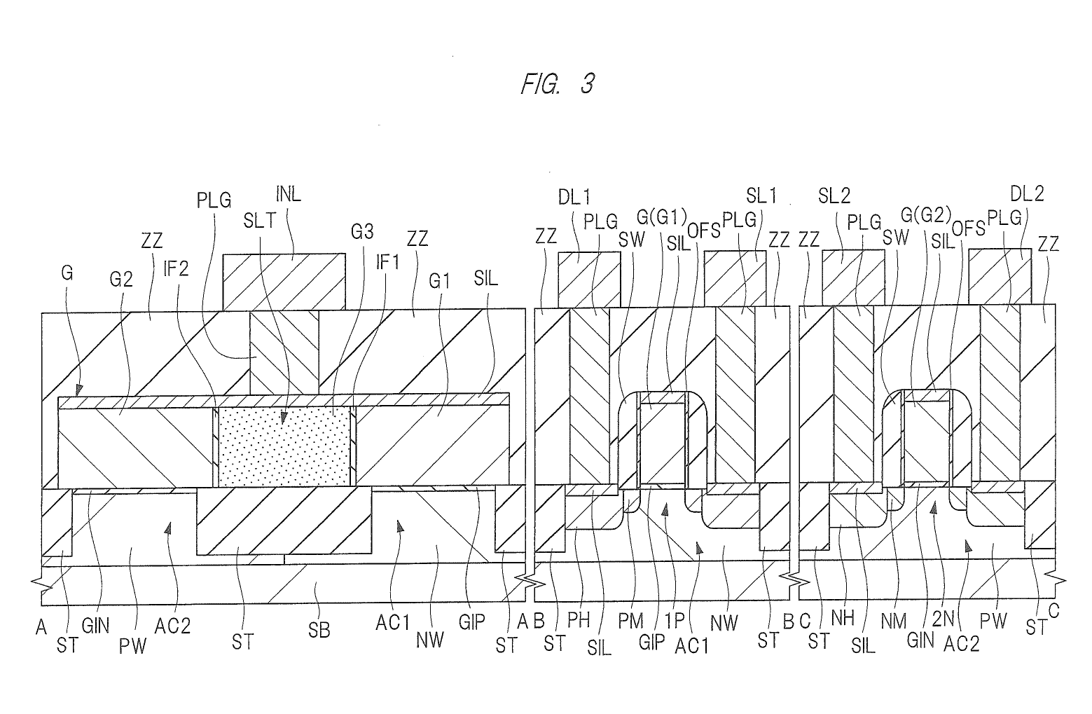

A semiconductor device according to the present first embodiment will be described with reference to drawings. FIG. 1 is an equivalent circuit diagram of an inverter circuit in the present first embodiment. FIG. 2 is a plan view illustrating a layout configuration example of the inverter circuit of the present first embodiment. The inverter circuit is configured of a complementary-type MISFET having a dual gate structure which is made up from a p-channel type MISFET having a p-type gate electrode and an n-channel type MISFET having an n-type gate electrode. FIG. 3 is a cross-sectional view of a principal part of the semiconductor device of the present embodiment, and illustrates an A-A cross-sectional surface, a B-B cross-sectional surface and a C-C cross-sectional surface of FIG. 2 so as to align them. The B-B cross-sectional surface is a cross-sectional surface of a p-channel type MISFET 1P in a channel length direction, and the C-C cross-sectional surface is a cross-sectional surface of an n-channel type MISFET 2N in a channel length direction. The A-A cross-sectional surface is cross-sectional surfaces of the p-channel type MISFET 1P and the n-channel type MISFET 2N in a gate width direction along the gate electrode G. In the A-A cross-sectional surface, gate widths of the p-channel type MISFET 1P and the n-channel type MISFET 2N are illustrated so as to be compressed.

As illustrated in FIG. 1, the inverter circuit is configured of the p-channel type MISFET 1P and the n-channel type MISFET 2N which are connected in series to each other between a power source potential VDD and a reference potential VSS. The p-channel type MISFET 1P is connected to the power source potential VDD side, and the n-channel type MISFET 2N is connected to the reference potential VSS side. The gate electrode of the p-channel type MISFET 1P and the gate electrode of the n-channel type MISFET 2N are electrically connected to each other, and these gate electrodes become an input IN of the inverter circuit. On the other hand, an output OUT of the inverter circuit becomes a connection portion between the p-channel type MISFET 1P and the n-channel type MISFET 2N.

Next, by using FIG. 2, the layout configuration of the inverter circuit will be described. As illustrated in FIG. 2, on a main surface of a semiconductor substrate, an active region AC1 and an active region AC2 are arranged so as to be aligned in a first direction, and the gate electrode G extends in the first direction so as to cross the active region AC1 and the active region AC2. This gate electrode G becomes an input of the inverter circuit. An element isolation region ISO is arranged so as to surround each of the active region AC1 and the active region AC2. In the element isolation region ISO, an element isolation film ST is arranged on the main surface of the semiconductor substrate.

The active region AC1 becomes a p-channel type MISFET 1P formation region, and the active region AC2 becomes an n-channel type MISFET 2N formation region. A source region and a drain region of the p-channel type MISFET 1P are formed in a pair of regions of the active region AC1 which sandwich the gate electrode G therebetween. Specifically, the drain region is formed in a left side region of the gate electrode G, and the source region is formed in a right side region of the gate electrode G. Furthermore, a source region and a drain region of the n-channel type MISFET 2N are formed in a pair of regions of the active region AC2 which sandwich the gate electrode G therebetween. Specifically, the source region is formed in a left side region of the gate electrode G, and the drain region is formed in a right side region of the gate electrode G.

The drain region of the p-channel type MISFET 1P is electrically connected to a drain wiring DL1 via a plug conductor layer, and this drain wiring DL1 is electrically connected with a power source wiring VDDL which supplies the power source potential. On the other hand, the source region of the p-channel type MISFET 1P is electrically connected to a source wiring SL1 via the plug conductor layer, and this source wiring SL1 is connected to an output wiring OUTL of the inverter circuit.

The drain region of the n-channel type MISFET 2N is connected to a drain wiring DL2 via a plug conductive layer, and this drain wiring DL2 is connected to the output wiring OUTL of the inverter circuit. On the other hand, the source region of the n-channel type MISFET 2N is connected to a source wiring SL2 via the plug conductor layer, and the source wiring SL2 is electrically connected to a reference potential wiring VSSL which supplies the reference potential.

In the element isolation region ISO between the active region AC1 where the p-channel type MISFET 1P is formed and the active region AC2 where the n-channel type MISFET 2N is formed, the gate electrode G is connected to an input wiring INL via the plug conductive layer.

Next, with reference to also FIG. 2, the semiconductor device of the present embodiment will be described by mainly using FIG. 3.

On the surface of the semiconductor substrate SB made of p-type silicon, a p-type well region PW where the n-channel type MISFET 2N is to be formed and an n-type well region NW where the p-channel type MISFET 1P is to be formed are formed. The p-channel type MISFET 1P is formed in the active region AC1 on the surface of the n-type well region NW, and the n-channel type MISFET 2N is formed in the active region AC2 on the surface of the p-type well region PW. The element isolation region ISO is arranged in the periphery of each of the active region AC1 and the active region AC2, and the element isolation film ST is formed on the main surface of the semiconductor substrate SB in the element isolation region ISO. That is, in each of the active region AC1 and the active region AC2, the periphery thereof is surrounded by the element isolation film ST. The element isolation film ST is formed of, for example, a silicon oxide film.

The p-channel type MISFET 1P is formed in the active region AC1, and the gate electrode G thereof is made of a first silicon section G1 formed on the main surface of the semiconductor substrate SB via a gate insulation film GIP. The first silicon section G1 is extended in the first direction from the active region AC1 to an upper portion of the element isolation film ST. The first silicon section G1 is made up from, for example, a polycrystalline silicon film containing a p-type (first conductivity type) impurity such as boron (B), and is a p-type conductor film. On the surface of the first silicon section G1, a silicide film SIL is formed. The source region and drain region of the p-channel type MISFET 1P are made up from a comparatively low-concentration p-type semiconductor region PM and a comparatively high-concentration p-type semiconductor region PH, and the silicide film SIL is formed on the surface of the high-concentration p-type semiconductor region PH. On a side wall of the first silicon section G1 as the gate electrode G, an offset spacer film OFS and a sidewall SW which are made up from, for example, a silicon oxide film are formed. The low-concentration p-type semiconductor region PM is positioned below the sidewall SW, and further, is positioned between the first silicon section G1 as the gate electrode G and the high-concentration p-type semiconductor region PH.

The gate insulation film GIP is formed of, for example, a silicon oxide film. However, in addition to that, the gate insulation film may be a silicon oxynitride film or a hafnium-based insulation film made of a hafnium oxide or others. The sidewall SW is formed of, for example, a silicon oxide film. However, the sidewall may have a stacked structure of the silicon oxide film and a silicon nitride film. In addition, the silicide film SIL is, for example, a platinum nickel silicide film, a nickel silicide film, a platinum silicide film, or others.

The n-channel type MISFET 2N is formed in the active region AC2, and the gate electrode G thereof is made up from a second silicon section G2 formed on the main surface of the semiconductor substrate SB via a gate insulation film GIN. The second silicon section G2 is extended in the first direction from the active region AC2 to an upper portion of the element isolation film ST. The second silicon section G2 is made up from the polycrystalline silicon film containing an n-type (second conductivity type) impurity such as phosphorus (P) or arsenic (As), and is an n-type conductor film. On the surface of the second silicon section G2, the silicide film SIL is formed. The source region and drain region of the n-channel type MISFET 2N is configured of a comparatively low-concentration n-type semiconductor region NM and a comparatively high-concentration n-type semiconductor region NH, and the silicide film SIL is formed on the surface of the high-concentration n-type semiconductor region NH. On a side wall of the second silicon section G2 as the gate electrode G, the offset spacer film OFS made up from, for example, a silicon oxide film, and the sidewall SW are formed. The low-concentration n-type semiconductor region NM is positioned below the sidewall SW, and further, is positioned between the second silicon section G2 as the gate electrode G and the high-concentration n-type semiconductor region NH. Here, as for the gate insulation film GIN, the same film as that of the gate insulation film GIP can be applied. In addition, as for the sidewall SW and the silicide film SIL, the same film as that of the p-channel type MISFET can be applied.

In addition, in FIG. 3, an interlayer insulation film ZZ covering the gate electrode G is made up from, for example, a silicon oxide film or a stacked film of a silicon nitride film and a silicon oxide film. The plug conductor layer PLG formed in the interlayer insulation film ZZ is made up from, for example, a tungsten film or a stacked film of a titanium nitride film and a tungsten film. The input wiring INL, the drain wiring DL1, the source wiring SL1, the source wiring SL2 and the drain wiring DL2 which are connected to the plug conductor layer PLG are made up from, for example, a metallic wiring film such as an aluminum film, a tungsten film and a copper film.

Next, the A-A cross-sectional surface of FIG. 2 will be described by using FIG. 3. On the main surface of the semiconductor substrate SB, the element isolation film ST and the active region AC1 and active region AC2 which are adjacent to the element isolation film ST so as to be positioned on both sides of the element isolation film ST are arranged. In the active region AC1 where the p-channel type MISFET 1P is to be formed, the first silicon section G1 as the p-type conductor film is arranged via the gate insulation film GIP. Then, in the active region AC2 where the n-channel type MISFET 2N is to be formed, the second silicon section G2 as the n-type conductor film is arranged via the gate insulation film GIN. Furthermore, on the element isolation film ST, a third silicon section G3 made up from, for example, the polycrystalline silicon film is arranged, and a first insulation film IF1 made up from, for example, the silicon oxide film is interposed between the first silicon section G1 and the third silicon section G3. Similarly, a second insulation film IF2 made up from, for example, a silicon oxide film is interposed between the second silicon section G2 and the third silicon section G3. The first insulation film IF1 and the second insulation film IF2 are positioned on the element isolation film ST. A conductor film made up from the silicide film SIL is formed continuously on each surface (upper surface) of the first silicon section G1, the first insulation film IF1, the second silicon section G2, the second insulation film IF2 and the third silicon section G3, and the first silicon section G1 and the second silicon section G2 are electrically connected to each other by this silicide film SIL. The silicide films SIL formed on the surfaces of the first silicon section G1, the third silicon section G3 and the second silicon section G2 are connected to each other so as to rise up over the first insulation film IF1 and the second insulation film IF2. As the result, an integral silicide film SIL is formed on the surfaces of the first silicon section G1, the first insulation film IF1, the second silicon section G2, the second insulation film IF2 and the third silicon section G3. Each film thickness of the first insulation film IF1 and second insulation film IF2 is 1 to 100 Å, and is thin enough to be able to prevent the impurity diffusion and to connect between adjacent silicon sections with the silicide film SIL. In addition, a film thickness of the third silicon section G3 is formed so as to be almost equal to each film thickness of the first silicon section G1 and the second silicon section G2, and the first silicon section G1 or the second silicon section G2 is easy to be connected to the third silicon section G3 with the silicide film SIL. That is, it can be said that the third silicon section G3 is a connection region for connecting the first silicon section G1 and the second silicon section G2 with the silicide film SIL.

In addition, as illustrated in FIG. 2, widths of the first silicon section G1, the second silicon section G2 and the third silicon section G3 in the second direction are equal to each other. In addition, widths of the first insulation film IF1 and second insulation film IF2 in the second direction are equal to widths of the first silicon section G1, the second silicon section G2 and the third silicon section G3. Note that FIG. 2 illustrates the first insulation film IF1 and the second insulation film IF2 with a line.

In addition, in FIG. 3, the gate electrode G is made up from the first silicon section G1, the second silicon section G2, the second silicon section G3, the first insulation film IF1, the second insulation film IF2 and the silicide film SIL, and is covered with the interlayer insulation film ZZ. The input wiring INL is arranged on the interlayer insulation film ZZ, and the gate electrode G and the input wiring INL are electrically connected to each other by one plug conductor layer PLG. Since the first silicon section G1 and the second silicon section G2 are electrically connected to each other by the silicide film SIL, the gate electrode G can be connected to the input wiring INL by one plug conductor layer PLG. Moreover, this plug conductor layer PLG is positioned on the element isolation film ST and the third silicon section G3, and is overlapped with the element isolation film ST and the third silicon section G3 when seen in a plan view. That is, since it is not required to provide the connection region with the plug conductor layer PLG to the first silicon section G1 and the second silicon section G2, the complementary-type MISFET can be downsized. In addition, since the plug conductor layer PLG is arranged on the third silicon section G3 as the connection region for electrically connecting the first silicon section G1 and the second silicon section G2, the complementary-type MISFET can be downsized. As a matter of course, it is always required to make the plug conductor layer PLG overlap the third silicon section G3 when seen in a plan view. However, it is not required to position the plug conductor layer completely on the third silicon section G3, and the plug conductor layer may be partially overlapped with the first silicon section G1 or the second silicon section G2.

A distance between the first silicon section G1 and the second silicon section G2 in the A-A cross-sectional surface of FIG. 3, i.e., in the first direction of FIG. 2 can be made very small (narrow). For example, the distance can be formed so as to be almost equal to the minimum processing dimension of manufacturing steps of the semiconductor device. This is because the impurity inter-diffusion between the p-type first silicon section G1 and the n-type second silicon section can be prevented by the very thin first insulation film IF1 or second insulation film IF2. This is because a height of the third silicon section G3 is only required to be enough to electrically connect the first silicon section G1 and second silicon section G2 by the silicide film SIL, and therefore, there is no particular limitation on a length in the first direction.

In addition, the third silicon section G3 and the second insulation film IF2 may be eliminated. In that case, the impurity inter-diffusion between the p-type first silicon section G1 and the n-type second silicon section can be prevented by the first insulation film IF1. A thickness of the first insulation film IF1 is only required to be thin enough to, on the first insulation film, connect the silicide film SIL on the first silicon section G1 and the silicide film SIL on the second silicon section G2, and is 1 to 100 Å as described above. In order to achieve the downsizing of the complementary-type MISFET, while it is always required to make the plug conductor layer PLG overlap the first insulation film IF1 when seen in a plan view, the plug conduction layer may be partially overlapped with the first silicon section G1 or the second silicon section G2.

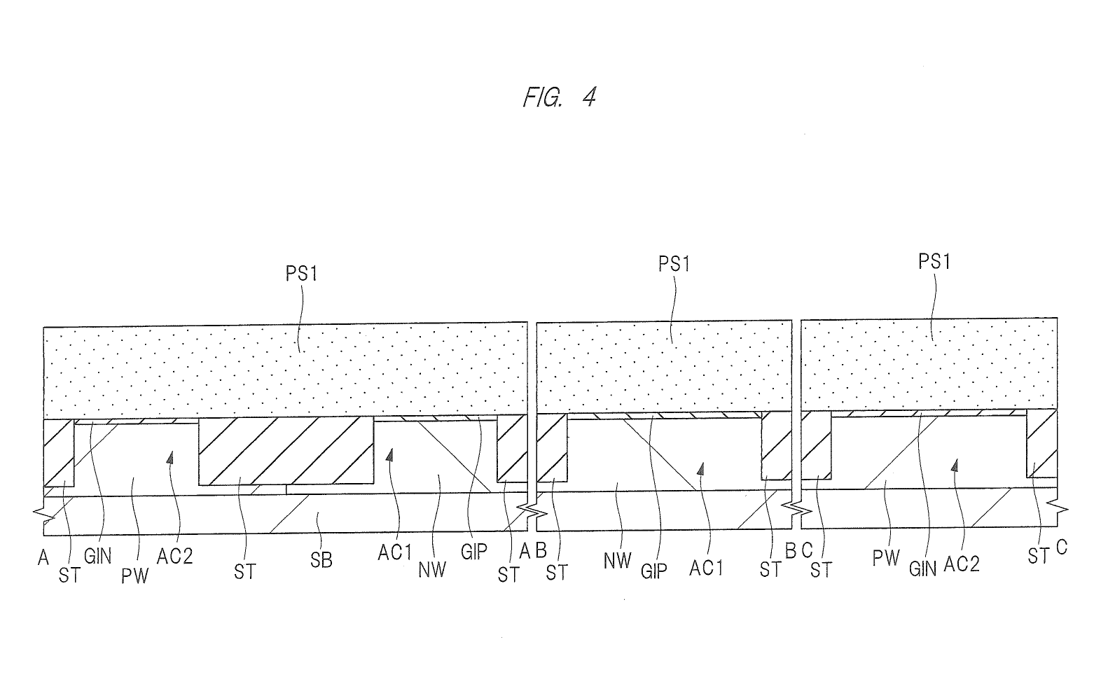

Each of FIGS. 4 to 17 illustrates a cross-sectional view of a principal part or a plan view of a principal part in a step of manufacturing the semiconductor device of the present embodiment illustrated in FIG. 3. Among FIGS. 4 to 17, FIG. 6 and FIG. 12 are plane views, and others are cross-sectional views. The cross-sectional views of FIGS. 4, 5, 7 to 11, and 13 to 17 illustrate the A-A cross-sectional surface, B-B cross-sectional surface and C-C cross-sectional surface in FIG. 2 so as to be aligned as described in FIG. 3.

FIG. 4 illustrates a step of forming the first silicon film PS1 on the semiconductor substrate SB. The first silicon film PS1 is deposited on the semiconductor substrate SB after the semiconductor substrate SB is prepared, the semiconductor substrate which has the arrangement as described in FIG. 2 and on which the element isolation film ST, active region AC1, active region AC2, n-type well region NW, p-type well region PW, gate insulation film GIP and gate insulation film GIN are formed. The first silicon film PS1 is a polycrystalline silicon film (polysilicon film) formed by a CVD (Chemical Vapor Deposition) method, and a film thickness thereof is about 150 to 250 nm.

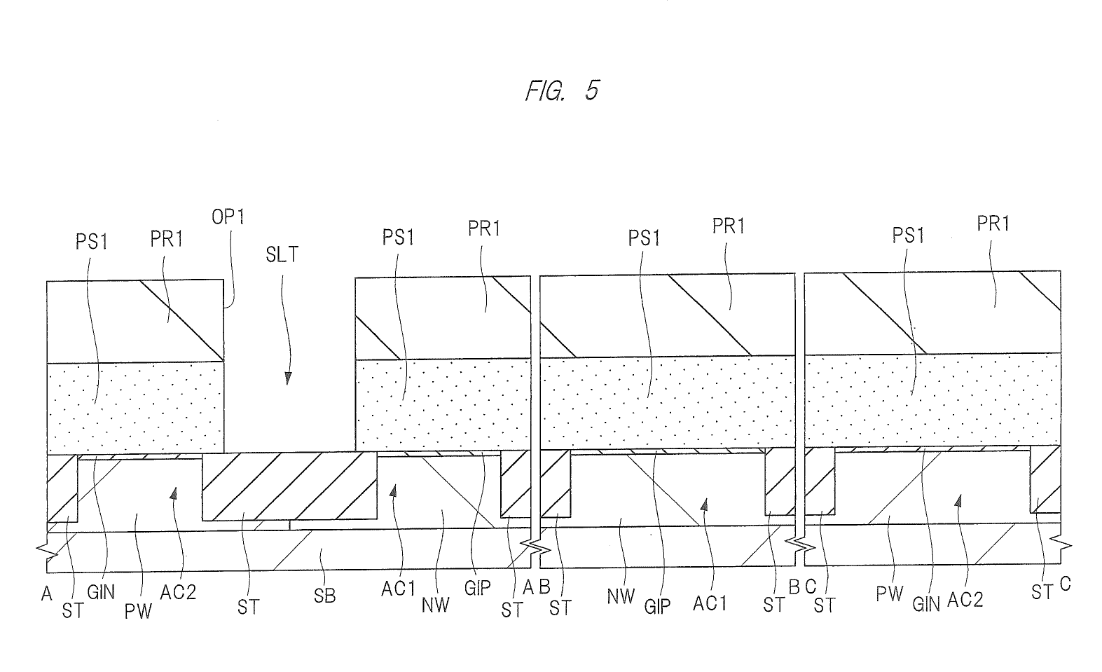

FIG. 5 illustrates a step of forming a slit SLT in the first silicon film PS1, continued from FIG. 4. A first photoresist film PR1 which has a first opening OP1 is formed on the first silicon film PS1, and the first silicon film PS1 is subjected to dry etching using the first photoresist film PR1 as a mask, so that the slit SLT is formed in the first silicon film PS1. The first photoresist film PR1 is made of, for example, an acrylic-based resin. The slit SLT penetrates through the first silicon film PS1 in a depth direction. The first photoresist film PR1 is removed after completion of the dry etching. Specifically, the first photoresist film PR1 is removed by, for example, a plasma ashing process using oxygen gas, and then, rinsing is performed by ammonia hydrogen peroxide water or sulfuric acid hydrogen peroxide water so as to remove residues of the first photoresist film PR1.

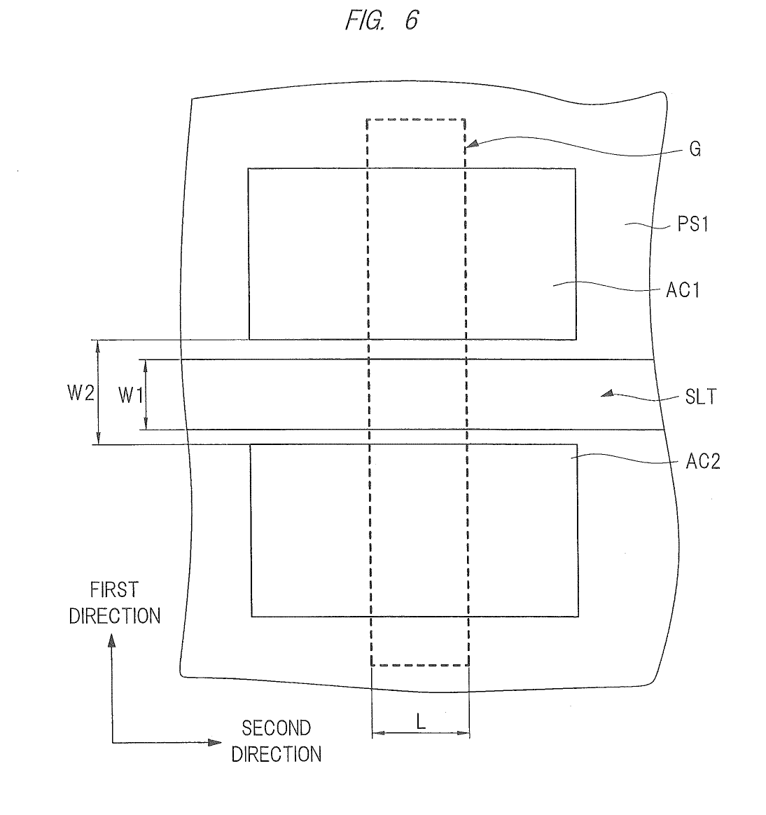

FIG. 6 is a plan view of a principal part illustrating a shape of the slit SLT of FIG. 5. In FIG. 6, the gate electrode G described in FIG. 2 is illustrated with a dashed line. The slit SLT is positioned on the element isolation film ST between the active region AC1 where the p-channel type MISFET 1P is to be formed and the active region AC2 where the n-channel type MISFET 2N is to be formed, and extends in the second direction so as to have a width W1 in the first direction. The width W1 of the slit SLT in the first direction is smaller than a width W2 of the element isolation film ST in the first direction, and the slit SLT is not protruded from the element isolation film ST in the first direction. On the other hand, the slit SLT is larger than a length L of the gate electrode G in the second direction, and extends so as to penetrate through the gate electrode G. In this stage, the gate electrode G on the active region AC1 and the gate electrode G on the active region AC2 are separated from each other by the slit SLT. Note that the width W1 of the slit SLT in the first direction can be such a minimum dimension as being able to open the slit SLT, and therefore, can be the minimum processing dimension of the steps manufacturing of the semiconductor device.

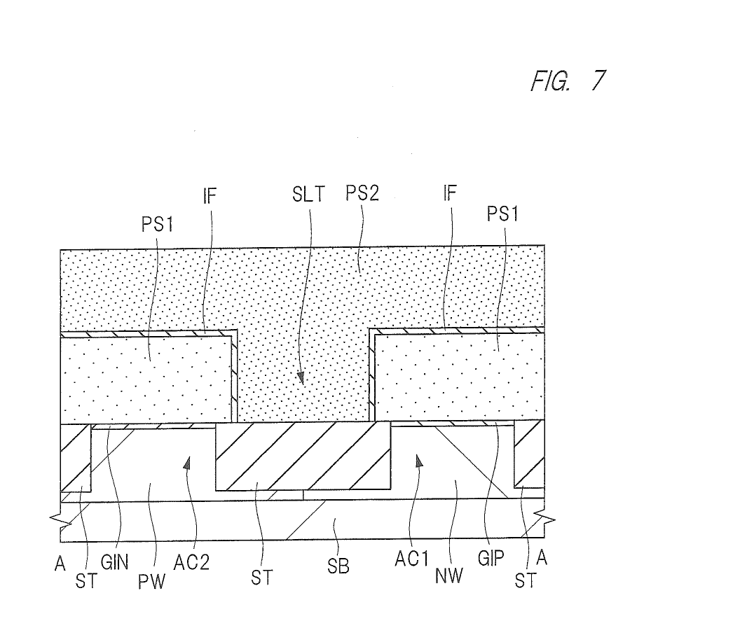

FIG. 7 is a cross-sectional view of a principal part illustrating a step of forming the insulation film IF and the second silicon film PS2, continued from FIG. 5. FIG. 7 illustrates only the A-A cross-sectional surface, and the B-B cross-sectional surface and C-C cross-sectional surface are omitted. As illustrated in FIG. 7, the insulation film IF is formed on an upper surface (main surface, front surface) of the first silicon film PS1 and a side wall (side surface, end surface) of the first silicon film PS1 in the slit portion. The insulation film IF is made up from the silicon oxide film whose film thickness is 1 to 100 Å. While the silicon oxide film is formed by a thermal oxidation method or a CVD method, a natural oxidation film (silicon oxide film) formed on the surface of the first silicon film PS1 in the step of rinsing the first photoresist film PR1 described above may be used alone. In addition, the silicon oxide film may have a stacked structure of the natural oxidation film and the silicon oxide film formed by the thermal oxidation method or a stacked structure of the natural oxidation film and the silicon oxide film by the CVD method. Then, the second silicon film PS2 is deposited inside the slit SLT and on the first silicon film PS1 (in detail, on the insulation film IF). The second silicon film PS2 is the polycrystalline silicon film (polysilicon film) formed by the CVD method, a non-crystalline silicon film (amorphous silicon film), or a silicon germanium film obtained by containing Ge in these films, and is formed so as to have such a thickness as completely filling the slit SLT. That is, since the width of the slit SLT in the first direction is W1, a film thickness of the second silicon film PS2 is set to “W1/2” or larger.

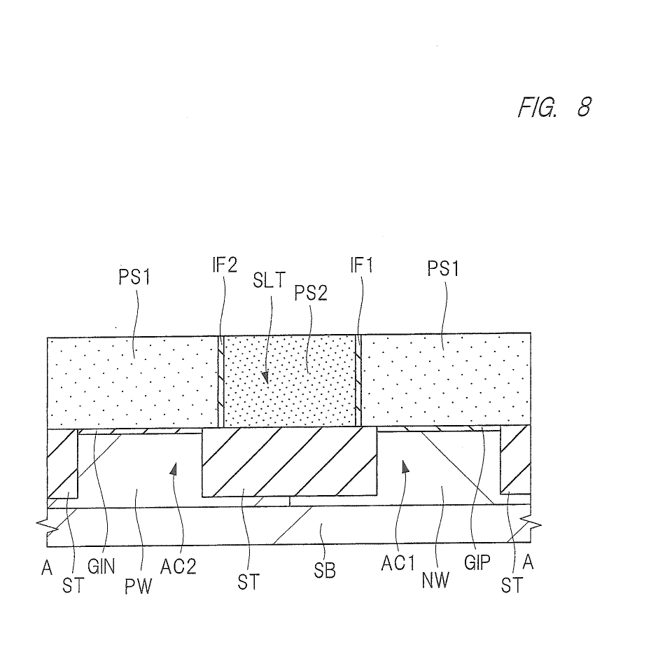

FIG. 8 is a cross-sectional view of a principal part illustrating the step of removing the second silicon film PS2 and the insulation film IF, continued from FIG. 7. FIG. 8 also illustrates only the A-A cross-sectional surface, and the B-B cross-sectional surface and the C-C cross-sectional surface are omitted. The second silicon film PS2 is subjected to the dry etching, and the second silicon film PS2 is selectively left in the slit SLT, and the second silicon film PS2 on the first silicon film PS1 is removed. In this dry etching, the insulation film IF on the first silicon film PS1 is functioned as an etching stopper. That is, the etching is performed on such a condition that an etching rate of the second silicon film PS2 becomes larger than an etching rate of the silicon oxide film forming the insulation film IF. Specifically, by using, for example, dry etching gas such as Br₂ and HBr, the etching rate of the second silicon film PS2 made up from the polycrystalline silicon film can be larger than the etching rate of the silicon oxide film. Then, by removing selectively the insulation film IF on the first silicon film P51, the structure illustrated in FIG. 8 is acquired. That is, the first insulation film IF1 is interposed between the first silicon film PS1 and second silicon film PS2 which are positioned on the p-channel type MISFET 1P formation region (active region AC1), and the second insulation film IF2 is interposed between the first silicon film PS1 and second silicon film PS2 which are positioned on the n-channel type MISFET 2N formation region (active region AC2). A film thickness of the second silicon film PS2 left selectively in the slit SLT is almost equal to a film thickness of the first silicon film PS1. After the steps described by using FIGS. 7 and 8 are performed, structures of the B-B cross-sectional surface and the C-C cross-sectional surface have become the structure illustrated in FIG. 4.

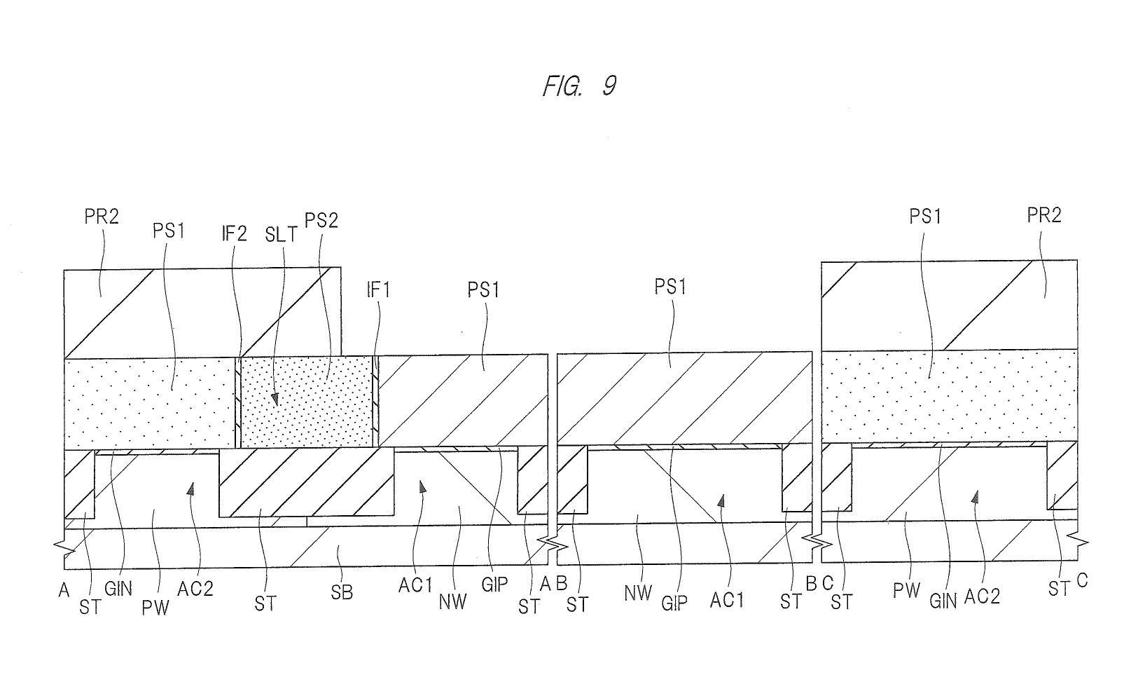

FIG. 9 is a cross-sectional view of a principal part illustrating a step of introducing a p-type impurity into the first silicon film PS1, continued from FIG. 8. A second photoresist film PR2 has a pattern which covers the n-channel type MISFET 2N formation region (active region AC2) and opens the p-channel type MISFET 1P formation region (active region AC1). As clearly seen from the A-A cross-sectional surface, an end portion of the second photoresist film PR2 is positioned on the second silicon film PS2, and FIG. 2 illustrates the end portion of this second photoresist film PR2 with a dashed line PP to PP. A p-type impurity is introduced into the first silicon film PS1 positioned in the opening of this second photoresist film PR2. The p-type impurity is, for example, boron, and the dose amount is about 5×10¹⁵ cm⁻². Therefore, a p-type impurity is introduced into the first silicon film PS1 positioned on the p-channel type MISFET formation region (active region AC1). Then, a p-type impurity is partially introduced into also the second silicon film PS2 in the A-A cross-sectional surface. The second photoresist film PR2 is removed after introducing the p-type impurity.

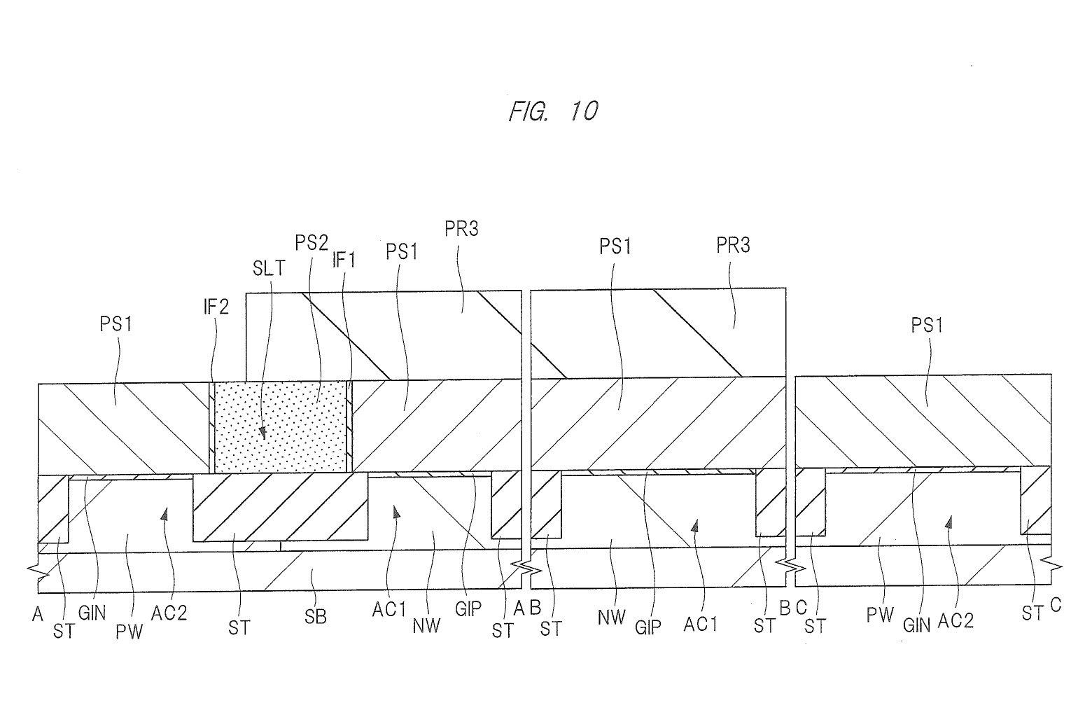

FIG. 10 is a cross-sectional view of a principal part illustrating a step of introducing an n-type impurity into the first silicon film PS1, continued from FIG. 9. A third photoresist film PR3 has a pattern which covers the p-channel type MISFET 1P formation region (active region AC1) and opens the n-channel type MISFET 2N formation region (active region AC2). As clearly seen from the A-A cross-sectional surface, an end portion of the third photoresist film PR3 is positioned on the second silicon film PS2, and FIG. 2 illustrates the end portion of this third photoresist film PR3 with a dashed line NN to NN. An n-type impurity is introduced into the first silicon film PS1 positioned in the opening of this third photoresist film PR3. The n-type impurity is, for example, phosphorus, and the dose amount is about 5×10¹⁵ cm⁻². Therefore, an n-type impurity is introduced into the first silicon film PS1 positioned on the n-channel type MISFET 2N formation region (active region AC2). Then, an n-type impurity is partially introduced into also the second silicon film PS2 in the A-A cross-sectional surface. The third photoresist film PS3 is removed after introducing the n-type impurity.

The explanation has been made here for the example in which the step of introducing the p-type impurity is performed before the step of introducing the n-type impurity. However, this order may be reverse. That is, the step of introducing the n-type impurity may be performed before the step of introducing the p-type impurity.

After removing the third photoresist film PS3, the semiconductor substrate SB is subjected to a heat process. By this heat process, boron as the p-type impurity and phosphorus as the n-type impurity which have been introduced into the first silicon film PS1 are activated. Although the p-type impurity and the n-type impurity are diffused by this heat process, the first insulation film IF1 is interposed between the first silicon film PS1 containing the p-type impurity and the second silicon film PS2 containing the n-type impurity on the p-channel type MISFET 1P formation region (active region AC1), and therefore, the impurity inter-diffusion is prevented. In addition, the second insulation film IF2 is interposed between the first silicon film PS1 containing the n-type impurity and the second silicon film PS2 containing the p-type impurity on the n-channel type MISFET 2N formation region (active region AC2), and therefore, the impurity inter-diffusion is prevented. As a matter of course, the first insulation film IF1 and the second insulation film IF2 are interposed between the first silicon film PS1 containing the p-type impurities on the p-channel type MISFET 1P formation region (active region AC1) and the first silicon film PS1 containing the n-type impurities on the n-channel type MISFET 2N formation region (active region AC2), and therefore, the impurity inter-diffusion is prevented. Even only the first insulation film IF1 or the second insulation film IF2 can prevent the impurity inter-diffusion between the first silicon film PS1 on the p-channel type MISFET 1P formation region (active region AC1) and the first silicon film PS1 on the n-channel type MISFET 2N formation region (active region AC2).

As described above, both the p-type impurity and the n-type impurity are introduced into the second silicon film PS2, and the p-type impurity and the n-type impurity are diffused in the second silicon film PS2 by the heat process, and therefore, it is not easy to specify the conductivity type of the second silicon film PS2. Therefore, hatching for the second silicon film PS2 in FIG. 9 and subsequent drawings is as the hatching at the time of forming the second silicon film PS2 illustrated in FIG. 7.

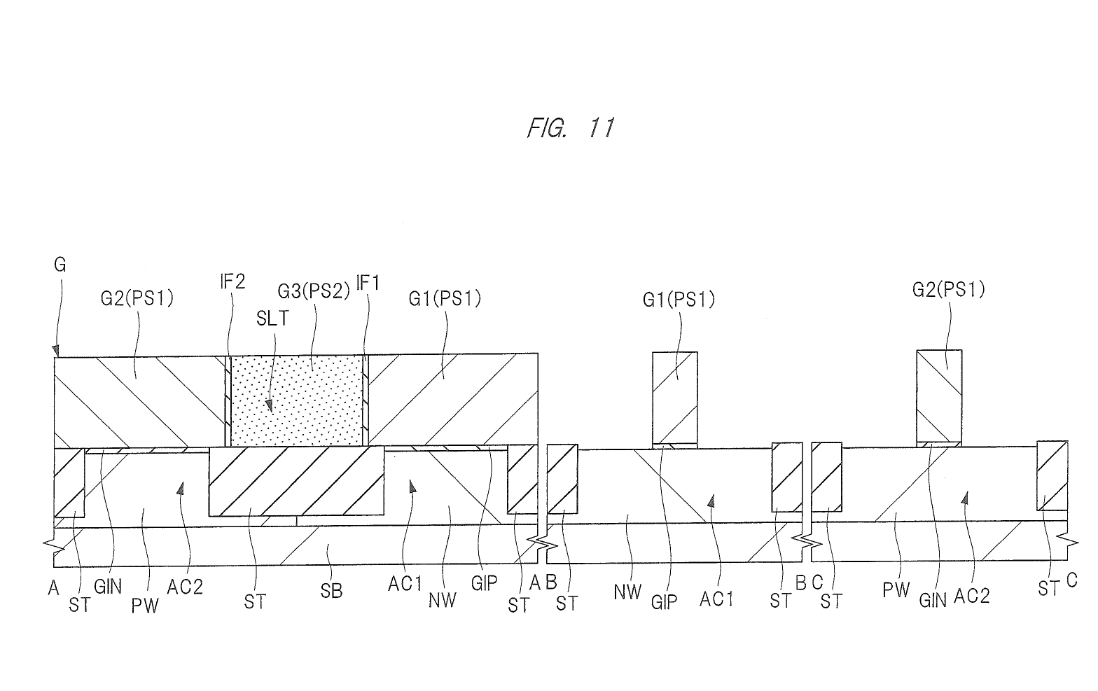

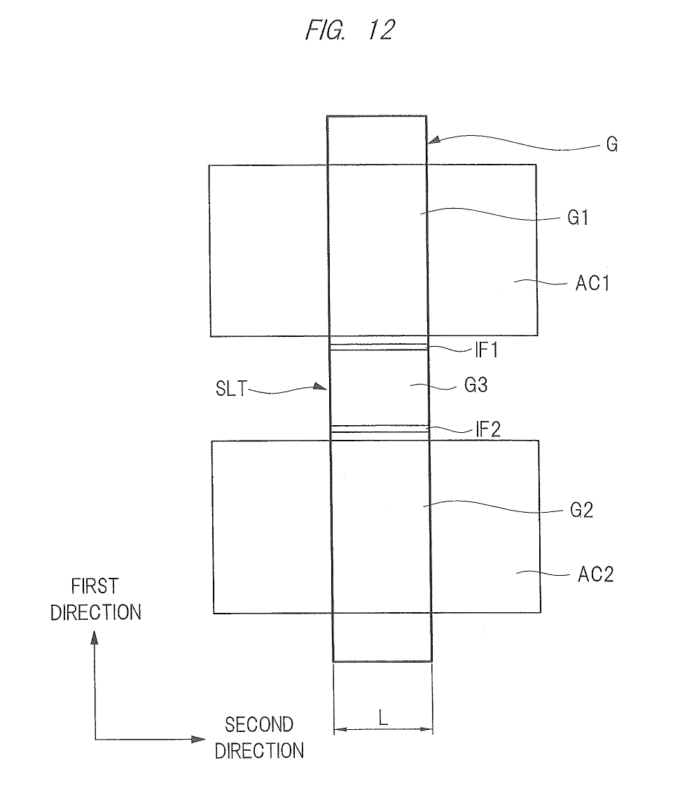

FIG. 11 is a cross-sectional view of a principal part illustrating the step of patterning the gate electrode G, continued from FIG. 10, and FIG. 12 illustrates a plan view of the patterned gate electrode G. The first silicon film PS1, the second silicon film PS2, the first insulation film IF1 and the second insulation film IF2 are subjected to dry etching using a not-illustrated photoresist film as a mask, so that the gate electrode G is formed. Although not illustrated, the pattern of the photoresist film is equal to a shape of the gate electrode G of FIG. 12. The gate electrode G includes the first silicon section G1, the second silicon section G2, the second silicon section G3, the first insulation film IF1 and the second insulation film IF2, and each of the first silicon section G1, the second silicon section G2, the second silicon section G3, the first insulation film IF1 and the second insulation film IF2 has a length L in the second direction. The first silicon section G1 becomes a gate electrode of the p-channel type MISFET 1P, and the second silicon section G2 becomes a gate electrode of the n-channel type MISFET 2N.

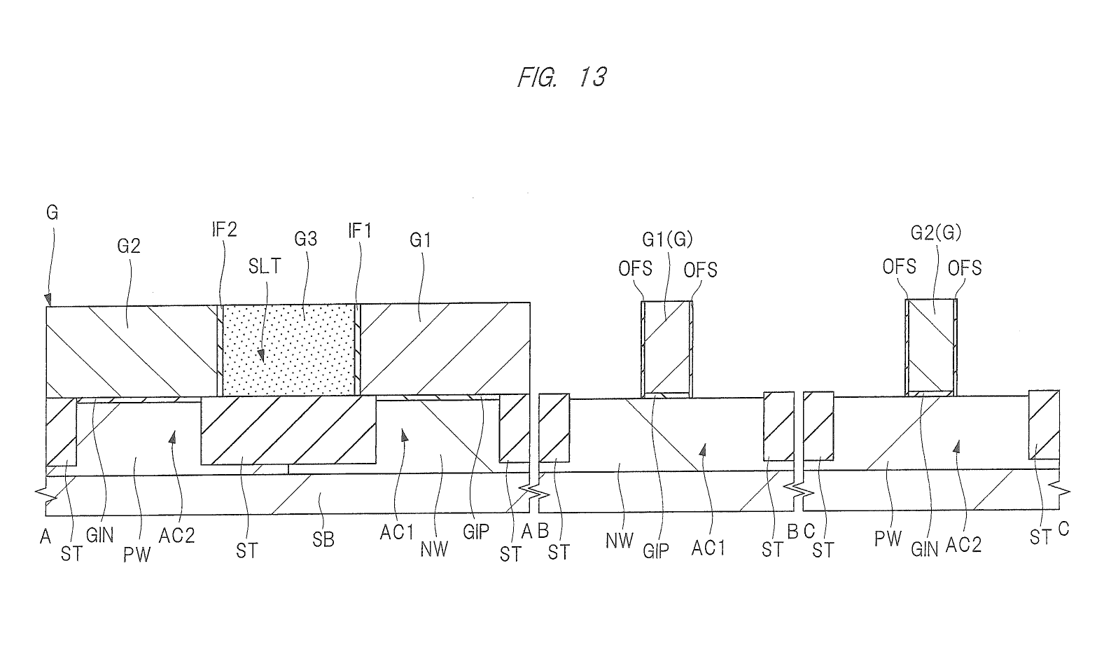

FIG. 13 is a cross-sectional view of a principal part illustrating a step of forming the offset spacer film OFS, continued from FIG. 11. The silicon oxide film is deposited by, for example, an ALD (Atomic Layer Deposition) method so as to cover the gate electrode G, specifically an upper surface and a side surface of the first silicon section G1 and second silicon section G2. The ALD method requires about two hours at a temperature of 400 to 500° C., and therefore, is one of severe processes in view of thermal load on the semiconductor substrate SB. Then, the deposited silicon oxide film is subjected to anisotropic etching, so that the offset spacer film OFS is formed on the side wall of the first silicon section G1 and the second silicon section G2.

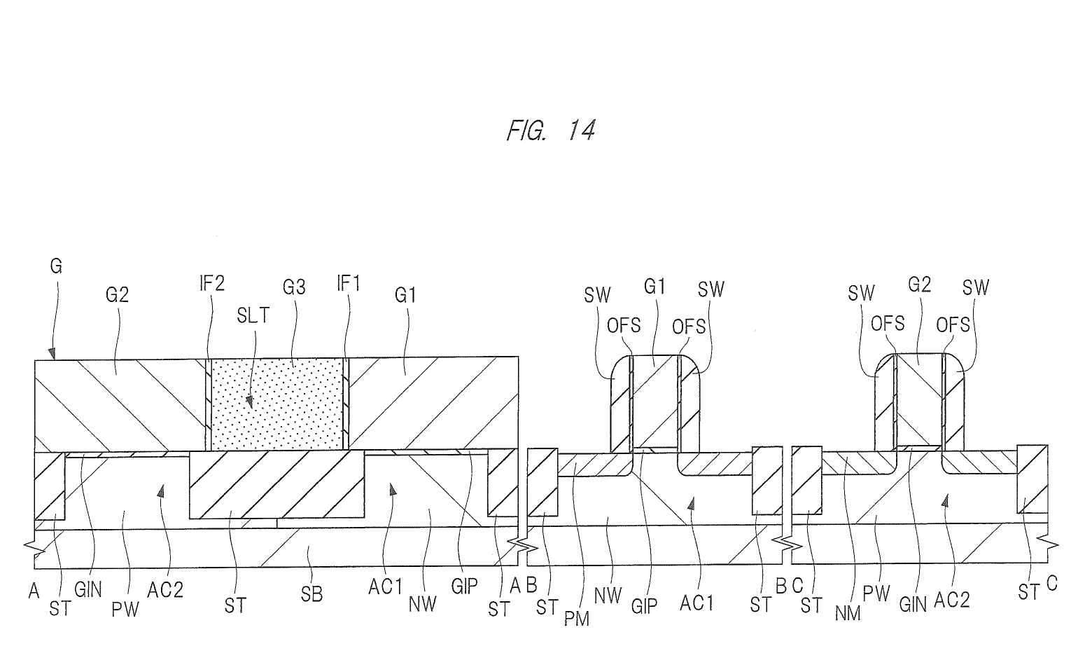

FIG. 14 is a cross-sectional view of a principal part illustrating a step of forming the low-concentration p-type semiconductor region PM, the low-concentration n-type semiconductor region NM and the sidewall SW, continued from FIG. 13. First, in the p-channel type MISFET 1P formation region (active region AC1), the low-concentration p-type semiconductor region PM is formed by introducing a p-type impurity, that is, boron fluoride into the main surface of the semiconductor substrate SB which is not covered with the first silicon section G1 and the offset spacer film OFS. The boron fluoride is introduced by an ion implantation method, and the dose amount is, for example, 5×10¹⁴ cm⁻². Next, in the n-channel type MISFET 2N formation region (active region AC2), the low-concentration n-type semiconductor region NM is formed by introducing an n-type impurity, for example, arsenic into the main surface of the semiconductor substrate SB which is not covered with the first silicon section G1 and the offset spacer film OFS. The arsenic is introduced by the ion implantation method, and the dose amount is, for example, 5×10¹⁴ cm⁻². Note that an order from the step of forming the low-concentration p-type semiconductor region PM to the step of forming the low-concentration n-type semiconductor region NM may be reverse. In order to activate the ion-implanted p-type impurity and n-type impurity, and restore the defects of the semiconductor substrate SB caused by the ion implantation, the semiconductor substrate SB is subjected to heat process. This heat process is lamp annealing, for example, at 900 to 1000° C. for 0.5 sec. Next, the sidewall SW is formed on the side wall of the gate electrode G by depositing the silicon oxide film on the semiconductor substrate SB by, for example, a CVD method and applying anisotropic etching to the silicon oxide film. That is, the sidewall SW is formed on the side wall of the first silicon section G1 and the second silicon section G2 via the offset spacer film OFS. The sidewall SW may be not only a single layer film of the silicon oxide film but also, for example, a laminated film of the silicon oxide film and the silicon nitride film.

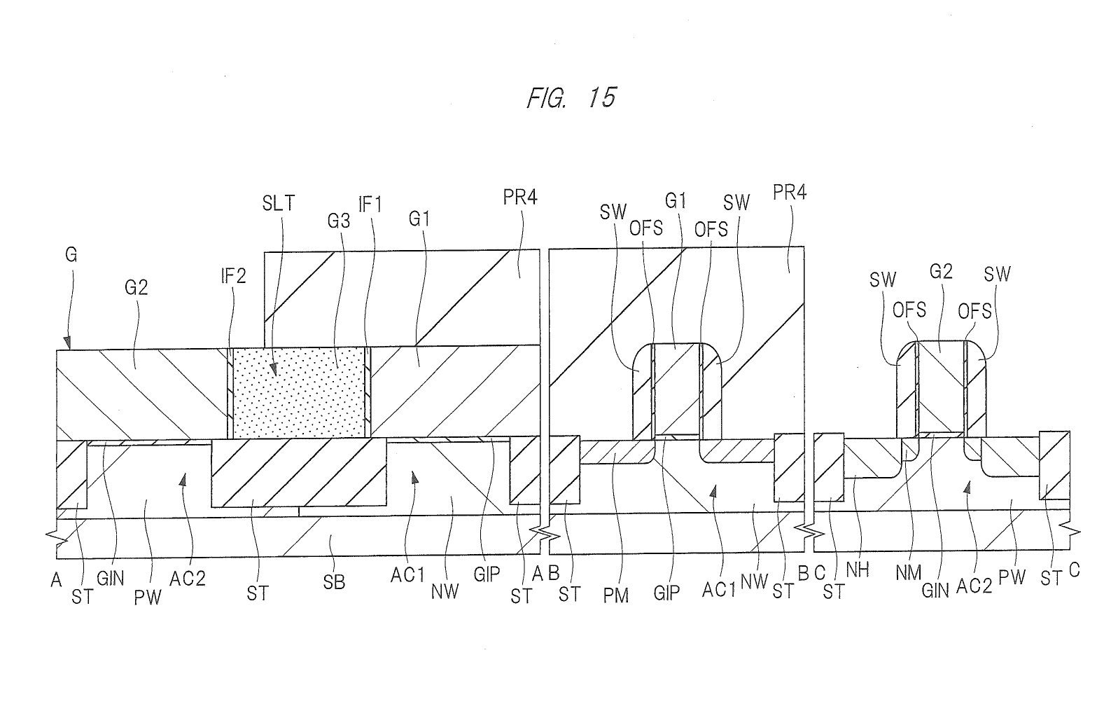

FIG. 15 is a cross-sectional view of a principal part illustrating the step of forming the high-concentration n-type semiconductor region NH, continued from FIG. 14. A fourth photoresist film PR4 has a pattern which covers the p-channel type MISFET 1P formation region (active region AC1), and opens the n-channel type MISFET 2N formation region (active region AC2). The fourth photoresist film PR4 has the same pattern as that of the third photoresist film PR3. By ion-implanting an n-type impurity into the semiconductor substrate SB surface while using the fourth photoresist film PR4 as a mask, the high-concentration n-type semiconductor region NH is formed in a region in the n-channel type MISFET 2N formation region (active region AC2) which is not covered with the second silicon section G2, the offset spacer film OFS and the sidewall SW. Since this opening of the fourth photoresist film PR4 exposes entirely the second silicon section G2 and partially the third silicon section G3, the n-type impurity is also introduced into entirely the second silicon section G2 and partially the third silicon section G3. The n-type impurity is, for example, arsenic, and the dose amount is about 5×10¹⁵ cm⁻². The fourth photoresist film PS4 is removed after introducing the n-type impurity.

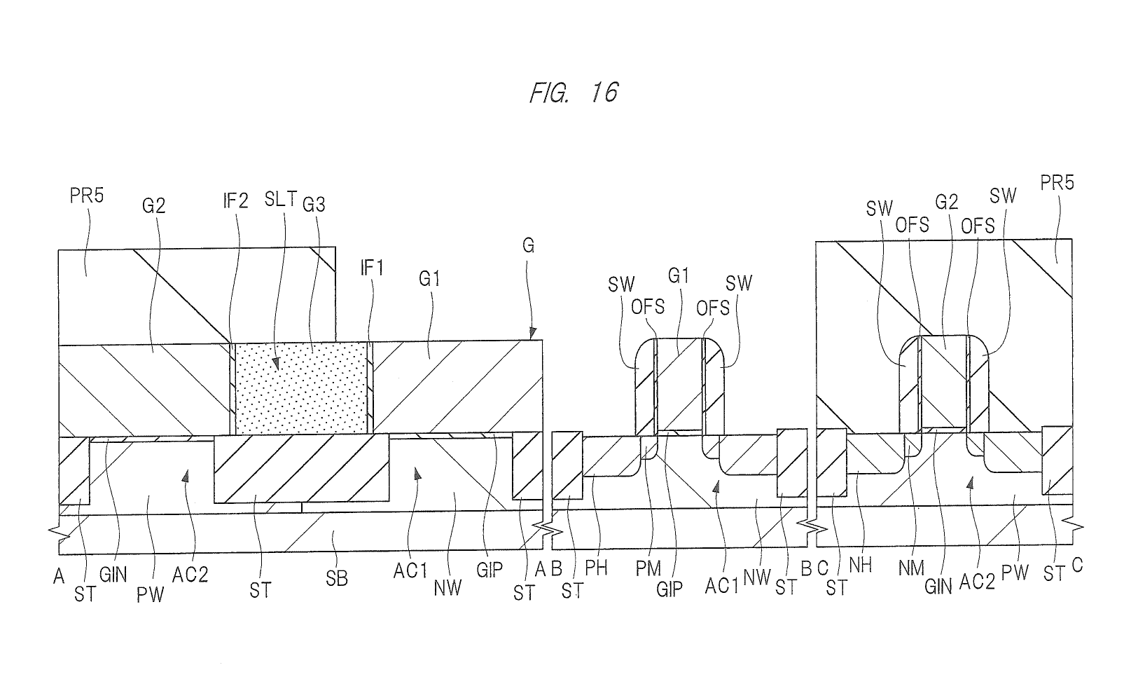

FIG. 16 is a cross-sectional view of a principal part illustrating a step of forming the high concentration p-type semiconductor region PH, continued from FIG. 15. A fifth photoresist film PR5 has a pattern which covers the n-channel type MISFET 2N formation region (active region AC2), and opens the p-channel type MISFET 1P formation region (active region AC1). The fifth photoresist film PR5 has the same pattern as that of the second photoresist film PR2. By ion-implanting the p-type impurity into the semiconductor substrate SB surface while using the fifth photoresist film PR5 as a mask, the high-concentration p-type semiconductor region PH is formed in a region in the p-channel type MISFET 1P formation region (active region AC1) which is not covered with the first silicon section G1, the offset spacer film OFS and the sidewall SW. Since this opening of the fifth photoresist film PR5 exposes entirely the first silicon section G1 and partially the third silicon section G3, the p-type impurity is also introduced into entirely the first silicon section G1 and partially the third silicon section G3. The p-type impurity is, for example, boron, and the dose amount is about 5×10¹⁵ cm⁻². The fifth photoresist film PS5 is removed after introducing the p-type impurity.

Here, the step of forming the high-concentration n-type semiconductor region NH has been described so as to be performed before the step of forming the high-concentration p-type semiconductor region PH. However, the step of forming the high-concentration p-type semiconductor region PH may be performed before the step of forming the high-concentration n-type semiconductor region NH.

After the step of introducing the n-type impurity described by using FIG. 15 and the step of introducing the p-type impurity described by using FIG. 16, the semiconductor substrate SB is subjected to a heat process in order to activate the introduced impurities. This heat process is lamp annealing, for example, at 1000 to 1100° C. for 0.5 sec. By this heat process, the p-type impurity and the n-type impurity which have been ion-implanted into the semiconductor substrate SB surface are activated. At the same time, by this heat process, the p-type impurity and the n-type impurity which have been introduced into the gate electrode G are diffused. However, the impurity inter-diffusion is prevented since the first insulation film IF1 is interposed between the first silicon section G1 containing the p-type impurity and the third silicon section G3 containing the n-type impurity on the p-channel type MISFET 1P formation region (active region AC1). In addition, the impurity inter-diffusion is prevented since the second insulation film IF2 is interposed between the second silicon section G2 containing the n-type impurity and the third silicon section G3 containing the p-type impurity on the n-channel type MISFET 2N formation region (active region AC2). As a matter of course, since at least the first insulation film IF1 or the second insulation film IF2 is interposed between the first silicon section G1 containing the p-type impurity on the p-channel type MISFET 1P formation region (active region AC1) and the second silicon section G2 containing the n-type impurity on the n-channel type MISFET 2N formation region (active region AC2), the impurity inter-diffusion is prevented.

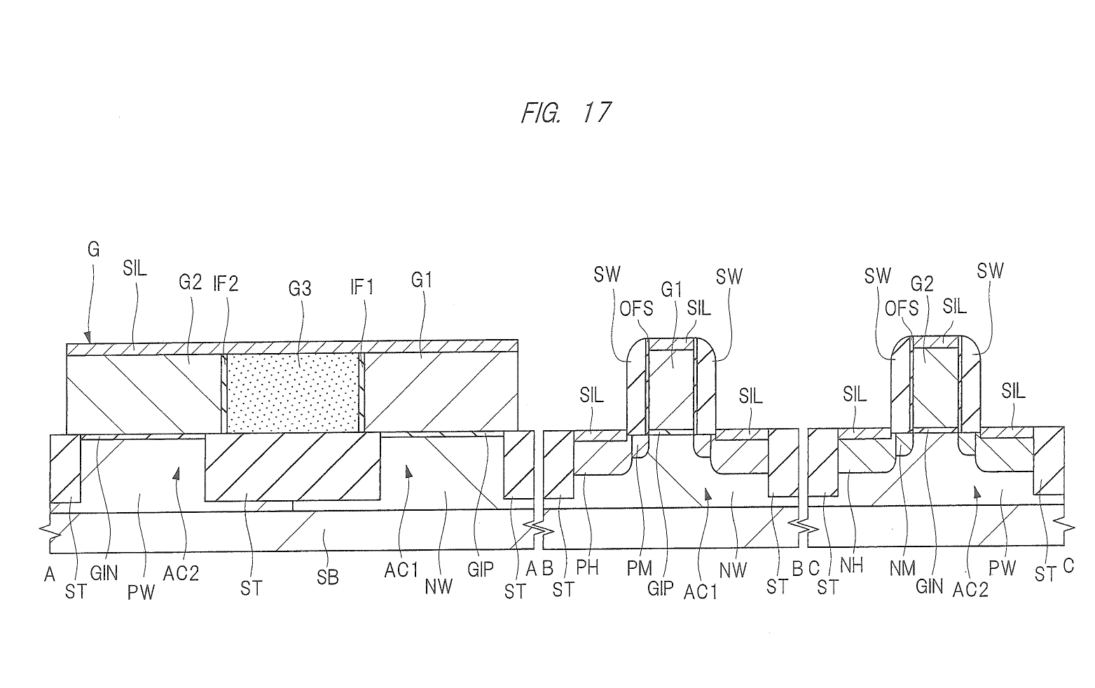

FIG. 17 is a cross-sectional view of a principal part illustrating a step of forming the silicide film SIL, continued from FIG. 16. A platinum nickel film as a nickel film obtained by adding platinum to the main surface of the semiconductor substrate SB is formed by using, for example, a sputtering method. Then, by applying a heat process at about 550° C. to the semiconductor substrate SB, silicide reaction is caused among the platinum nickel film, the semiconductor substrate made of silicon, the platinum nickel film and the polycrystalline silicon film, so that the silicide film SIL is formed. Then, by removing the platinum nickel film in a portion where the silicide reaction has not been caused, the silicide film SIL made of the platinum nickel silicide is formed on the high-concentration p-type semiconductor region PH, the high-concentration n-type semiconductor region NH, the first silicon section G1, the second silicon section G2 and the third silicon section G3. In the A-A cross-sectional surface of FIG. 17, the first silicon section G1, the second silicon section G2 and the third silicon section G3 are electrically connected to each other by the silicide films SIL formed on their surfaces. Since the thicknesses of the first insulation film IF1 and the second insulation film IF2 are thin, the silicide films SIL formed on the surfaces of the first silicon section G1, the second silicon section G2 and the third silicon section G3 are formed integrally (continuously) with each other so as to be beyond the first insulation film IF1 and the second insulation film IF2. The formation of the film thickness of the third silicon section G3 so as to be almost equal to the film thicknesses of the first silicon section G1 and the second silicon section G2 is effective for integrally (continuously) forming the silicide film SIL.

Then, the interlayer insulation film ZZ is formed so as to cover the p-channel type MISFET 1P and the n-channel type MISFET 2N. The interlayer insulation film ZZ is made up from the silicon oxide film formed by, for example, a plasma CVD method. Although not illustrated, by forming a plurality of openings in the interlayer insulation film ZZ and selectively filling insides of the openings with a conductor film, the plug conductor layer PLG is formed. Next, a metallic wiring film is deposited on the interlayer insulation film ZZ, and this metallic wiring film is processed into a desired pattern. In this manner, the semiconductor device illustrated in FIG. 3 is completed.

In the present embodiment, the explanation have been made for the example of performing the step of introducing the p-type impurity and the step of introducing the n-type impurity into the first silicon film PS1 after performing the step of forming the slit SLT in the first silicon film PS1, the step of forming the insulation film IF and the second silicon film PS2, and the step of removing the second silicon film PS2 and the insulation film IF, and then, performing the heat process (activation). However, the step of introducing the p-type impurity and the step of introducing the n-type impurity into the first silicon film PS1 may be performed first, and then, the step of forming the slit SLT in the first silicon film PS1, the step of forming the insulation film IF and the second silicon film PS2, and the step of removing the second silicon film PS2 and the insulation film IF may be performed. Then, the heat process for activating the p-type impurity and the n-type impurity which have been introduced into the first silicon film PS1 may be performed. In this case, the step of forming the second silicon film PS2 and the step of removing the second silicon film PS2 and the insulation film IF may be performed after the heat process for activating the p-type impurity and the n-type impurity which have been introduced into the first silicon film PS1.

In the present embodiment, depletion of the gate electrode G is suppressed as much as possible by introducing a great amount of the p-type impurity into the first silicon section G1 as the gate electrode G of the p-channel type MISFET 1P and introducing a great amount of the n-type impurity into the second silicon section G2 as the gate electrode G of the n-channel type MISFET 2N, so that a higher-performance semiconductor device is provided. For that, into the first silicon section G1, the high-concentration p-type impurity is introduced by two steps. One of them is the step of introducing the p-type impurity into the first silicon film PS1 described by using FIG. 9, and the other is the step of forming the high-concentration p-type semiconductor region PH described by using FIG. 16. In addition, the high-concentration n-type impurity is introduced also into the second silicon section G2 by two steps, and one of them is the step of introducing the n-type impurity introduction into the first silicon film PS1 described by using FIG. 10, and the other is the step of forming the high-concentration n-type semiconductor region NH described by using FIG. 15. However, the step of introducing the p-type impurity into the first silicon film PS1 and the step of introducing the n-type impurity into the first silicon film PS1 described above can also be eliminated.

In the present embodiment, the explanation has been made for the example of applying the complementary-type MISFET having the dual gate structure to the inverter circuit. However, it is needless to say that the present embodiment can be applied to any circuit as long as the circuit has the complementary-type MISFET having the dual gate structure. For example, the present embodiment may be applied to a p-channel type MISFET for a load and an n-channel type MISFET for driving which configure a SRAM memory cell.

Next, main feature and effect of the present embodiment will be described.

The main feature of the present embodiment is that the insulation film IF is interposed between the first silicon section G1 which has the p-type impurity and the second silicon section G2 which has the n-type impurity. Because of this feature, the impurity inter-diffusion between the first silicon section G1 and the second silicon section G2 can be prevented, and the increase in the threshold voltage of the complementary-type MISFET can be suppressed. In addition, reduction in an on-current can be suppressed. In addition, a separation width (W2) between the p-channel type MISFET 1P and the n-channel type MISFET 2N can be reduced.

In addition, the first silicon section G1 and the second silicon section G2 are electrically connected to each other by the silicide film continuously formed on the surfaces of the first silicon section G1, the insulation film IF and the second silicon section G2. Therefore, it is not required to connect the plug conductor layer with each of the first silicon section G1 and the second silicon section G2 for electrically connecting the first silicon section G1 and the second silicon section G2, and an integration degree of the semiconductor device can be improved.

The third silicon section G3 is interposed between the first silicon section G1 and the second silicon section G2, and the first insulation film IF1 is interposed between the first silicon section G1 and the third silicon section G3, and the second insulation film IF2 is interposed between the second silicon section G2 and the third silicon section G3. Therefore, the inter-diffusion between the first silicon section G1 and the second silicon section G2, the inter-diffusion between the first silicon section G1 and the third silicon section G3 and the inter-diffusion between the second silicon section G2 and the third silicon section G3 can be prevented.

The first silicon section G1 and the second silicon section G2 are electrically connected to each other by the silicide film continuously formed on the surfaces of the first silicon section G1, the first insulation film IF1, the third silicon section G3, the second insulation film IF2 and the second silicon section G2. Therefore, it is not required to connect the plug conductor layer to each of the first silicon section G1 and the second silicon section G2 for electrically connecting the first silicon section G1 and the second silicon section G2, so that the integration degree of the semiconductor device can be improved.

The plug conductor layer PLG is provided at a position which is overlapped with the third silicon section G3 when seen in a plan view, and the first silicon section G1 as the gate electrode G of the p-channel type MISFET 1P and the second silicon section G2 as the gate electrode G of the n-channel type MISFET 2N are connected to the metallic wiring film (such as input wiring INL) via the silicide film SIL by one plug conductor layer PLG. Therefore, since it is not required to connect the plug conductor layer to each of the first silicon section G1 and the second silicon section G2, and the region where the third silicon section G3 is arranged when seen in a plan view can be used as the connection region between the gate electrode G and the metallic wiring film (such as input wiring INL), and therefore, the integration degree of the semiconductor device can be improved.

In addition, according to the method of manufacturing the semiconductor device of the present embodiment, the step of forming the slit SLT in the first silicon film PS1 and the step of forming the insulation film IF are performed before performing the heat process for activating the p-type impurity and the n-type impurity which have been introduced into the first silicon film PS1, and therefore, the inter-diffusion between the p-type impurity and the n-type impurity which have been introduced into the first silicon film PS1 can be prevented.

The ion-implantation for forming the high-concentration p-type semiconductor region PH and the ion-implantation for forming the high-concentration n-type semiconductor region NH are performed after forming of the gate electrode G made up from the first silicon section G1, the first insulation film IF1, the third silicon section G3, the second insulation film IF2 and the second silicon section G2. Then, the heat process for activating the p-type impurity and the n-type impurity which have been ion-implanted into the semiconductor substrate SB surface is performed, and therefore, the impurity inter-diffusion caused in the heat process can be prevented.

Boundaries of the photo masks for the ion implantation in the step of introducing the p-type impurity into the first silicon film PS1, in the step of introducing the n-type impurity into the first silicon film PS1, in the step of forming the high-concentration n-type semiconductor region NH and in the step of forming the high-concentration p-type semiconductor region PH may be positioned on the second silicon film PS2 or the third silicon section G3. Furthermore, the width of the second silicon film PS2 or the third silicon section G3 can be the minimum processing dimension. Therefore, the separation width (W2) between the p-channel type MISFET 1P and the n-channel type MISFET 2N can be reduced.

In addition, since the film thickness of the second silicon film PS2 for filling up the slit SLT is almost equal to that of the first silicon film PS1 in the step of patterning the gate electrode G in FIG. 11, the patterning can be highly accurately performed.

### Second Embodiment

The present second embodiment is a modification example of the above-mentioned first embodiment.

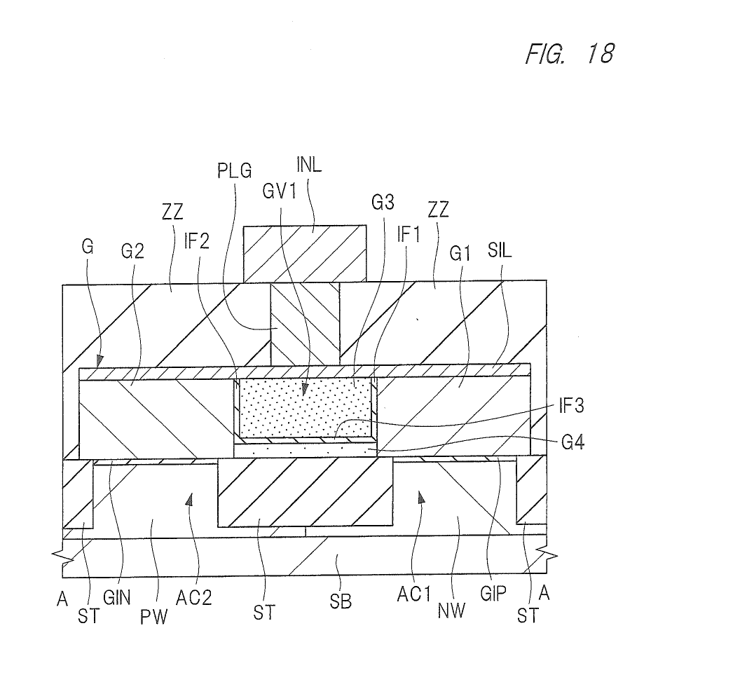

Although FIG. 18 illustrates a cross-sectional view of a principal part of a semiconductor device of the first modification example corresponding to FIG. 3, only illustrates an A-A cross-sectional surface.

Replacement of the slit SLT of FIG. 3 by a groove GV1 is a feature point of the first modification example, and other points are the same as those of the semiconductor device of the above-mentioned first embodiment.

As illustrated in FIG. 18, by replacing the slit SLT by the groove GV1, a fourth silicon section G4 remains below the groove GV1, and the first silicon section G1 and the second silicon section G2 are connected to each other by the fourth silicon section G4. And, a third insulation film IF3 is formed between the fourth silicon section G4 and the third silicon section G3 filling an inside of the groove GV1.

According to the present second embodiment, even if the inter-diffusion between the first silicon section G1 containing the p-type impurity and the second silicon section G2 containing the n-type impurity cannot be completely prevented, a diffusion path can be narrowed in the thickness direction of the gate electrode G, and therefore, the inter-diffusion can be suppressed.

Furthermore, in the present second embodiment, it is allowed that the groove GV1 is formed so as to be protruded from the upper portion of the element isolation film ST toward the upper portion of the active region AC1 or the active region AC2. That is, it is not required to form a width of the element isolation film ST to be larger than a width of the groove GV1 in consideration of an overlap margin in the lithography or others. In other words, the width of the element isolation film ST can be smaller than the width of the groove GV1, and therefore, the micro-fabrication of the semiconductor device can be achieved. This is because, in explanation for a case of, for example, the protrusion (positional shift) of the groove GV1 onto the active region AC1, the protrusion does not affect a threshold of the p-channel type MISFET formed in the active region AC1 even when a predetermined input voltage is applied to the input wiring INL since the third insulation film IF3 and the fourth silicon section G4 exist below the third silicon section G3.

### Third Embodiment

The present third embodiment is a modification example of the above-described first embodiment.

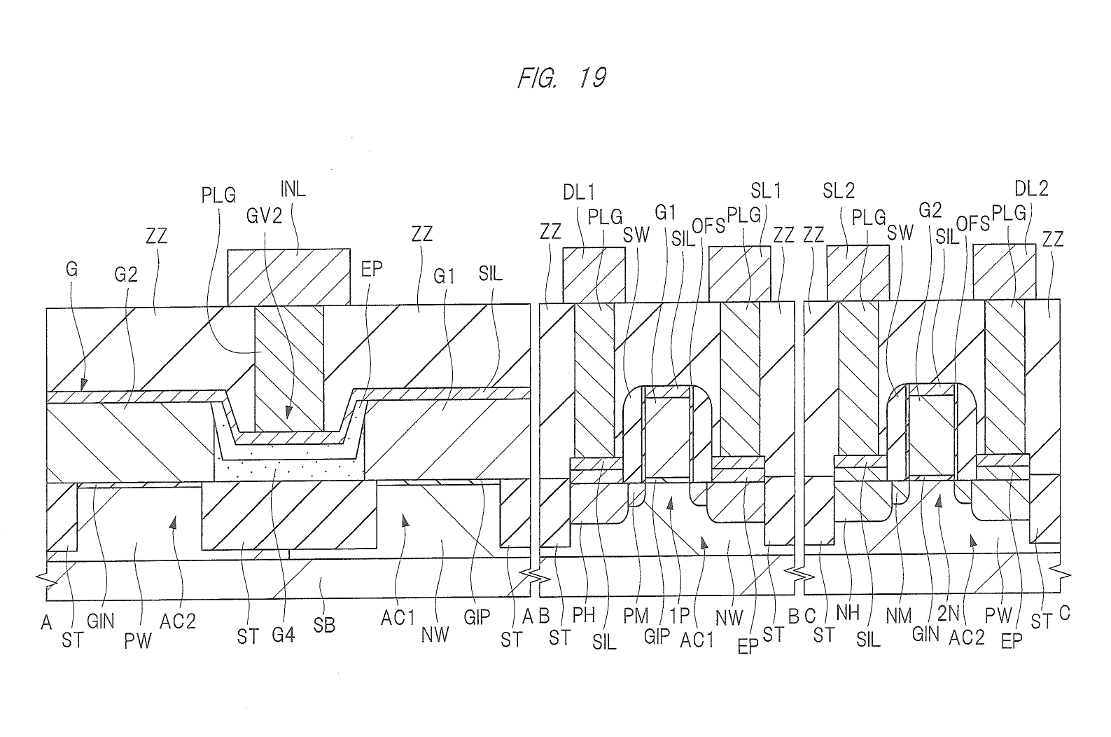

FIG. 19 illustrates a cross-sectional view of a principal part of a semiconductor device of the present third embodiment, and corresponds to FIG. 3 of the first embodiment. The common components with those in FIG. 3 are denoted by the same symbols. Different points of the present third embodiment from the first embodiment are as follows. First, not the slit SLT but the groove GV2 is formed between the first silicon section G1 and the second silicon section G2, the gate electrode G is not separated, and the first silicon section G1 and the second silicon section G2 are connected to each other by the fourth silicon section G4 having a film thickness thinner than that of the first silicon section G1 or the second silicon section G2. Next, an epilayer EP made up from a silicon film is formed on the surface of the groove GV2. A shape of the groove GV2 when seen in a plan view is the same as that of the slit SLT of the first embodiment. In addition, the epilayer EP made up from the silicon film is formed on the surface of the high-concentration p-type semiconductor region PH of the p-channel type MISFET 1P and the surface of the high-concentration n-type semiconductor region NH of the n-channel type MISFET 2N, and the silicide film SIL is formed on the surface of the epilayer.

According to the present third embodiment, in the A-A cross-sectional surface, a portion between the first silicon section G1 and second silicon section G2 of the gate electrode G is thinner than the film thickness of the first silicon section G1 or the second silicon section G2 since the groove GV2 has been formed. In addition, while the epilayer EP is formed on the surface of the groove GV2, a total film thickness of the fourth silicon section G4 and the epilayer EP is smaller than the film thickness of the first silicon section G1 or the second silicon section G2. Therefore, the impurity inter-diffusion between the first silicon section G1 containing the p-type impurity and the second silicon section G2 containing the n-type impurity can be suppressed.

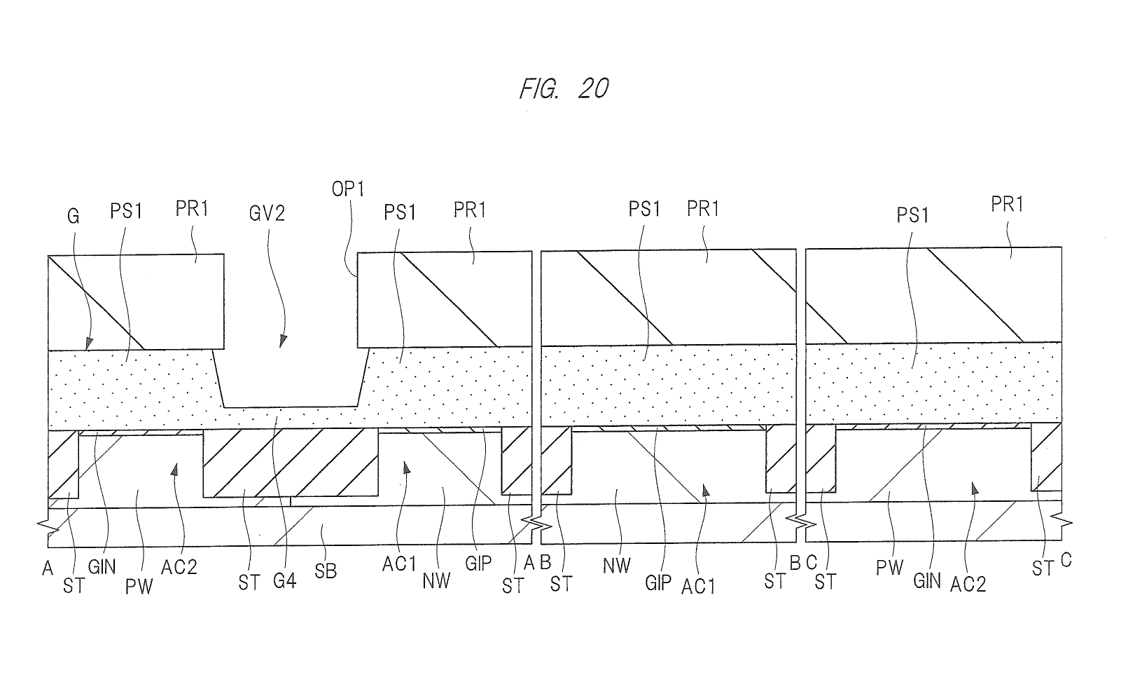

Hereinafter, a method of manufacturing the semiconductor device of the present third embodiment will be described by using FIGS. 20 to 26.

FIG. 20 is a cross-sectional view of a principal part illustrating a step of introducing an impurity into the first silicon film PS1 and a step of forming the groove GV2 in the first silicon film PS1. FIG. 20 corresponds to FIGS. 9, 10, and 5 of the first embodiment. First, the first silicon film PS1 is deposited on the semiconductor substrate SB. Next, the n-channel type MISFET 2N formation region (active region AC2) is covered with a photoresist film which is not illustrated, and a p-type impurity (such as boron) is introduced into the first silicon film PS1 on the p-channel type MISFET 1P formation region (active region AC1). Next, the p-channel type MISFET 1P formation region (active region AC1) is covered with a photoresist film which is not illustrated, and an n-type impurity (such as phosphorus) is introduced into the first silicon film PS1 on the n-channel type MISFET 2N formation region (active region AC2). Next, an impurity which suppresses epitaxial growth such as nitrogen (N), carbon (C), germanium (Ge) or others is introduced into the surface of the first silicon film PS1. Next, as illustrated in FIG. 20, by applying dry etching to the first silicon film PS1 while using the first photoresist film PR1 as a mask, the groove GV2 is formed in the first silicon film PS1. The groove GV2 does not penetrate through the first silicon film PS1 in a depth direction, and the fourth silicon section G4 remains in a bottom portion of the groove GV2. A side surface of the groove GV2 is processed in a tapered shape, and an opening diameter of the upper portion of the groove GV2 is larger than an opening diameter of the bottom portion thereof. Note that the impurity which suppresses the epitaxial growth is also removed simultaneously in the groove GV2 portion by the above-described dry etching.

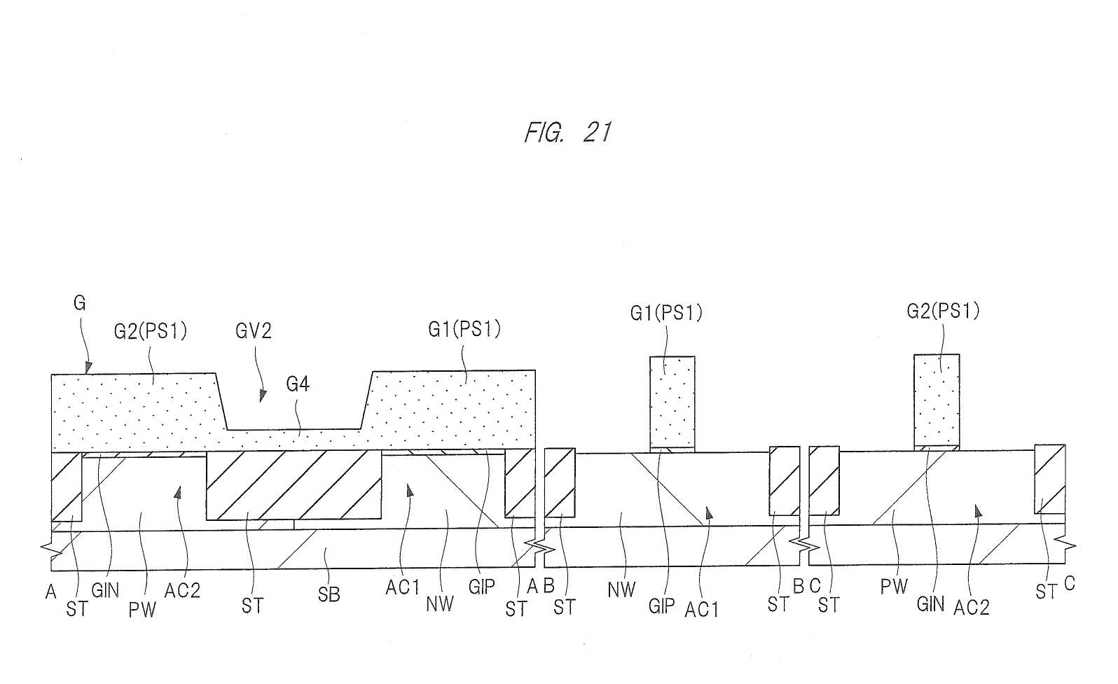

FIG. 21 is a cross-sectional view of a principal part illustrating the step of patterning the gate electrode G, and corresponds to FIG. 11 of the first embodiment. By applying dry etching to the first silicon film PS1 while using a not illustrated photoresist film as a mask, the gate electrode G is formed. The gate electrode G is made up from the first silicon section G1, the second silicon section G2 and the fourth silicon section G4, and has such a planar shape that the first insulation film IF1 and the second insulation film IF2 are removed from FIG. 12, and that the third silicon section G3 changes to the fourth silicon section G4.

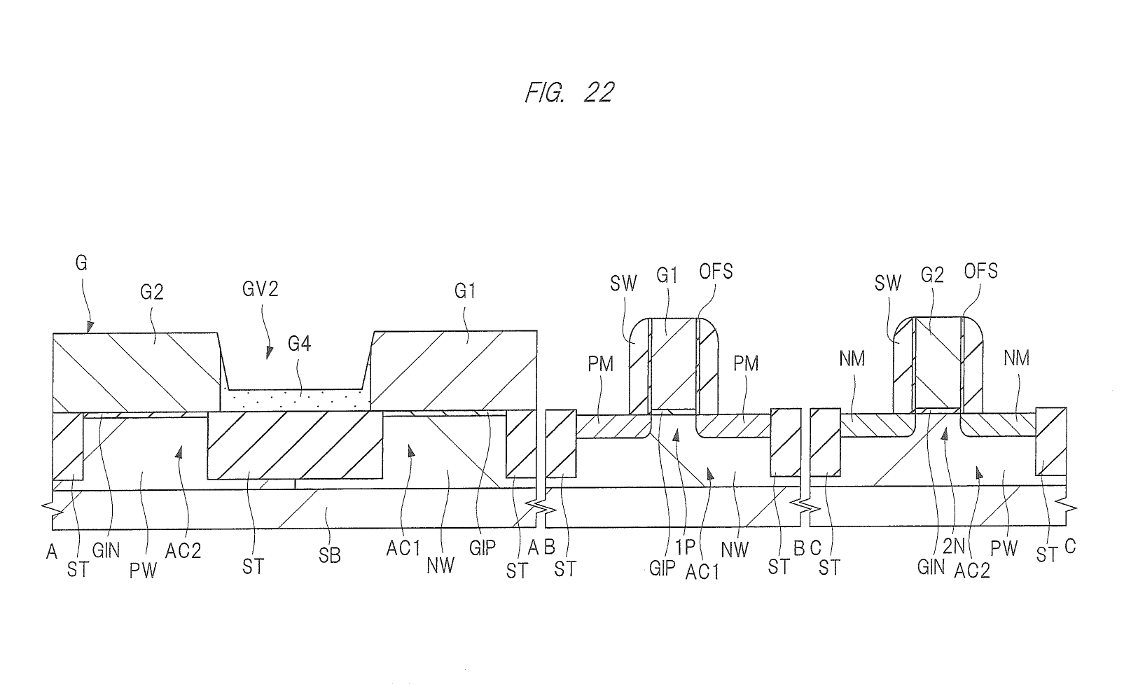

FIG. 22 is a cross-sectional view of a principal part for describing the step of forming the offset spacer film OFS, the low-concentration p-type semiconductor region PM, the low-concentration n-type semiconductor region NM and the sidewall SW, corresponds to FIGS. 13 and 14 of the first embodiment, and descriptions for them are also the same. In a step of forming the sidewall SW, since the side wall of the groove GV2 of the gate electrode G is processed in a tapered shape, the sidewall is not formed on the side surface of the groove GV2.

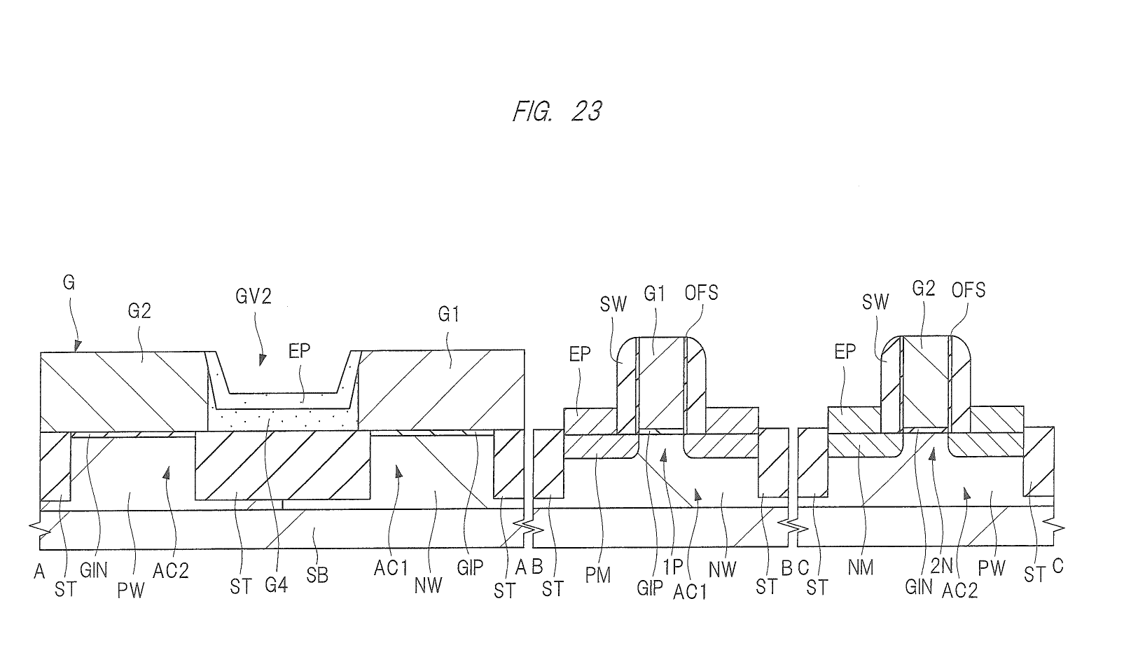

FIG. 23 is a cross-sectional view of a principal part illustrating a step of forming the epilayer EP. The epilayer EP made up from the silicon film is formed selectively by an epitaxial growth method on the surfaces of the low-concentration p-type semiconductor region PM of the p-channel type MISFET 1P, the low-concentration n-type semiconductor region NM of the n-channel type MISFET and the groove GV2. In this epitaxial growth, the impurity which suppresses the epitaxial growth is introduced into the surfaces of the first silicon section G1 and second silicon section G2 of the gate electrode G, and therefore, the epilayer EP is not formed thereon. In addition, in the groove GV2 portion, a total film thickness of the fourth silicon section G4 and the epilayer EP is smaller than a film thickness of the first silicon section G1 or the second silicon section G2.

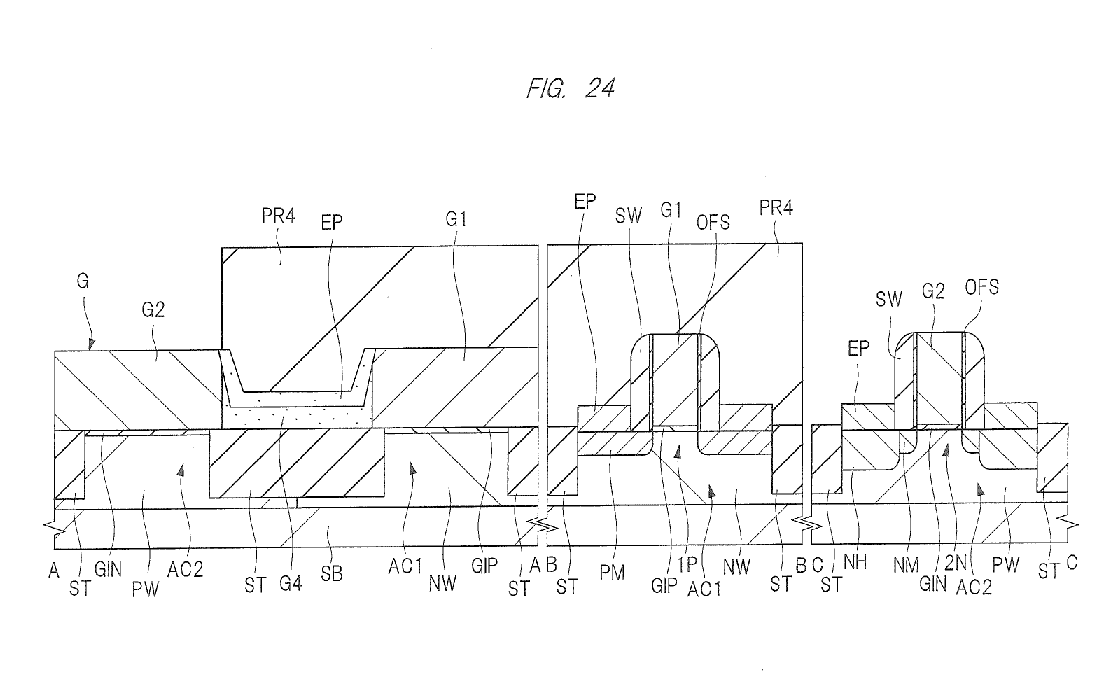

FIG. 24 is a cross-sectional view of a principal part illustrating a step of forming the high-concentration n-type semiconductor region NH, and corresponds to FIG. 15 of the first embodiment. By ion-implanting the n-type impurity into the semiconductor substrate SB surface while using the fourth photoresist film PR4 as a mask, the high-concentration n-type semiconductor region NH is formed in a region in the n-channel type MISFET 2N formation region (active region AC2) which is not covered with the second silicon section G2, the offset spacer film OFS and the sidewall SW. Furthermore, the n-type impurity is introduced also into the epilayer EP portion formed on the surface of the low-concentration n-type semiconductor region NM of the n-channel type MISFET 2N. The n-type impurity is introduced also into the second silicon section G2 exposed from the fourth photoresist film PR4. The impurity, the concentration and others in the ion implantation are the same as those of the first embodiment.

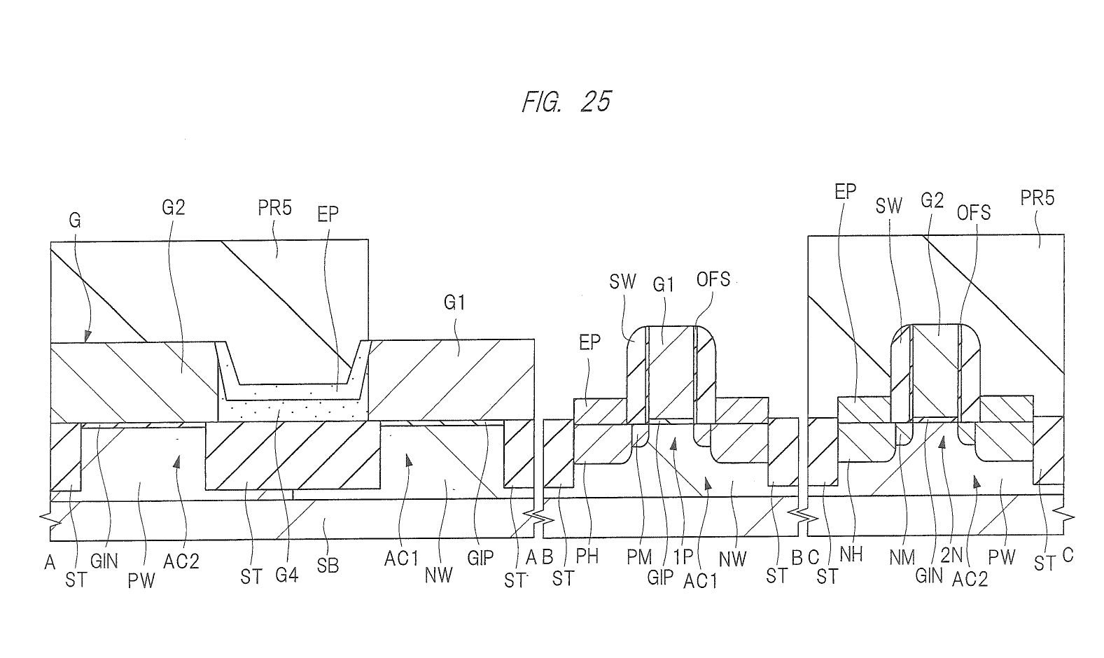

FIG. 25 is a cross-sectional view of a principal part illustrating a step of forming the high-concentration p-type semiconductor region PH. FIG. 25 corresponds to FIG. 16 of the first embodiment. By ion-implanting the p-type impurity into the semiconductor substrate SB surface while using the fifth photoresist film PR5 as a mask, the high-concentration p-type semiconductor region PH is formed in a region in the p-channel type MISFET 1P formation region (active region AC1) which is not covered with the first silicon section G1, the offset spacer film OFS and the sidewall SW. Further, the p-type impurity is introduced also into the epilayer EP portion formed on the surface of the low-concentration p-type semiconductor region PM of the p-channel type MISFET 1P. The p-type impurity is introduced also into the first silicon section G1 exposed from the fifth photoresist film PR5. The impurity, the concentration and others in the ion implantation are the same as those of the first embodiment.

Next, the semiconductor substrate SB is subjected to a heat process in order to activate the p-type impurity introduced into the first silicon section G1 and the n-type impurity introduced into the second silicon section G2. Conditions of this heat process are the same as those of the first embodiment. By this heat process, the p-type impurity and the n-type impurity which have been introduced into the gate electrode G are diffused. However, the impurity inter-diffusion is reduced since the total film thickness of the fourth silicon section G4 and the epilayer EP in the groove GV2 portion is thin.

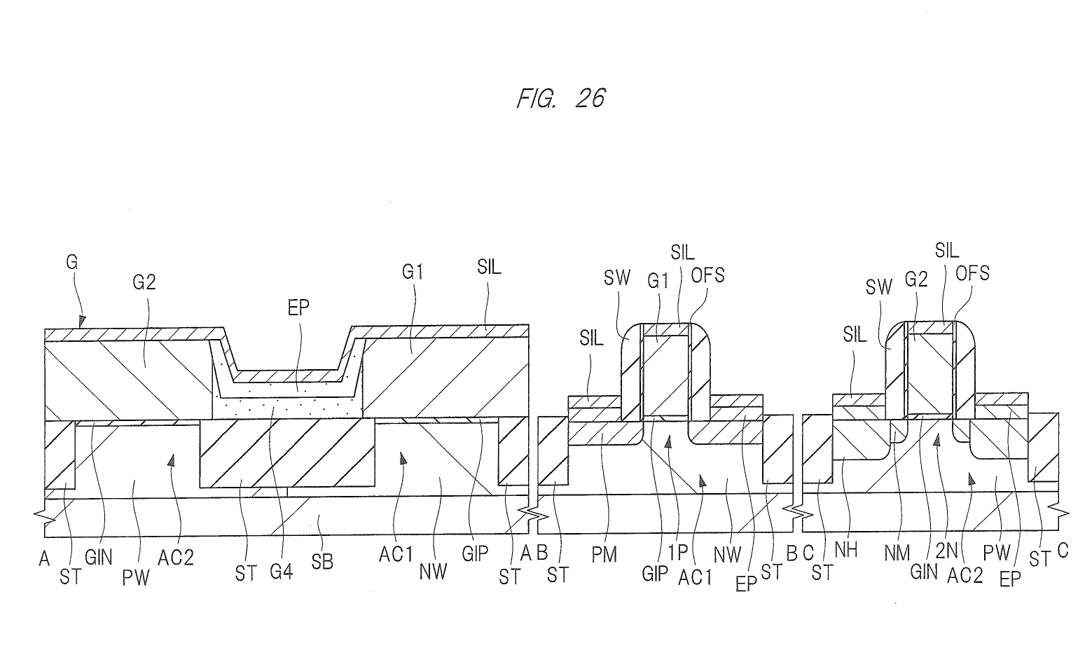

FIG. 26 is a cross-sectional view of a principal part illustrating a step of forming the silicide film SIL. FIG. 26 corresponds to FIG. 17 of the first embodiment. The silicide film SIL is formed on the surfaces of the first silicon section G1, the second silicon section G2 and the epilayer EP. The formation conditions of the silicide film SIL are the same as those of the first embodiment.

Next, the interlayer insulation film ZZ, the plug conductor layer PLG and the metallic wiring layer are formed, so that the semiconductor device having the structure illustrated in FIG. 19 is formed.

According to the present third embodiment, effects described in the second embodiment can be achieved. Furthermore, since the epilayer EP is formed on the fourth silicon section G4 in the groove GV2 in the step of forming the epilayer EP in the p-channel type MISFET 1P and the n-channel type MISFET 2N, the step can be simplified.

By forming the epilayer EP on the fourth silicon section G4 in the groove GV2, difference in a height among the fourth silicon section G4, the first silicon section G1, and the second silicon section G2 can be reduced, and the silicide film SIL connecting between the first silicon section G1 and the second silicon section G2 can be prevented from being separated in the groove GV2 portion.

The present invention is not limited to the above-described embodiments, and includes various modification examples. The above-described first to third embodiments have been described in detail for understandably describing the present invention, and are not necessarily limited to one provided with all of the described configuration. In addition, the configuration of one embodiment can also be partially replaced by the configuration of the other embodiment. In addition, the configuration of the other embodiment can also be added to the configuration of one embodiment. In addition, other configurations can be added to/eliminated from/replaced with partially the configuration of each embodiment.

Note that, the following invention is also included in the present application.

A semiconductor device includes: a semiconductor substrate which has a main surface and has an element isolation region and first and second active regions which are arranged so as to be adjacent to the element isolation region in a first direction of the main surface; an element isolation film made up from an insulation film formed on the main surface of the semiconductor substrate in the element isolation region; a first gate insulation film formed on the main surface of the semiconductor substrate in the first active region; a second gate insulation film formed on the main surface of the semiconductor substrate in the second active region; a first silicon section which is formed on the first gate insulation film in the first active region and contains an impurity of a first conductivity type; a second silicon section which is formed on the second gate insulation film in the second active region and contains an impurity of a second conductivity type which is an opposite conductivity type to the first conductivity type; and a fourth silicon section which is formed on the element isolation film in the element isolation region. In the semiconductor device, the first silicon section and the second silicon section are connected to each other by the fourth silicon section, and a film thickness of the fourth silicon section is thinner than film thicknesses of the first silicon section and the second silicon section.

### SYMBOL EXPLANATION

AC1 and AC2 active region
EP epilayer
G gate electrode
GIN and GIP gate insulation film
GV1 and GV2 groove
G1, G2, G3, and G4 silicon section
IF, IF1, and IF2 insulation film
IN input
ISO element isolation region
OUT output
OFS offset spacer film
NW and PW well region
NM, NH, PM, and PH semiconductor region
OP1 opening
PLG plug conductor layer
PR1, PR2, PR3, PR4, and PR5 photoresist film
PS1 and PS 2 silicon film
SE semiconductor substrate
SIL silicide film
SLT slit
ST element isolation film
SW sidewall
VDD power source potential
VSS reference potential
VDDL, VSSL, INL, OUTL, DL1, SL1, DL2, and SL2 wire
ZZ interlayer insulation film
1P p-channel type MISFET
2N n-channel type MISFET

1. A semiconductor device comprising:
a semiconductor substrate which has a main surface and has an element isolation region and first and second active regions which are arranged so as to be adjacent to the element isolation region in a first direction of the main surface;
an element isolation film made up from an insulation film formed on the main surface of the semiconductor substrate in the element isolation region;
a first gate insulation film formed on the main surface of the semiconductor substrate in the first active region;
a second gate insulation film formed on the main surface of the semiconductor substrate in the second active region;
a first silicon section which is formed on the first gate insulation film in the first active region and contains an impurity of a first conductivity type;
a second silicon section which is formed on the second gate insulation film in the second active region and contains an impurity of a second conductivity type which is an opposite conductivity type to the first conductivity type;
an insulation film which is positioned on the element isolation film and is interposed between the first silicon section and the second silicon section; and
a first conductor film which is continuously formed on surfaces of the first silicon section, the insulation film and the second silicon section,
wherein the first silicon section and the second silicon section are electrically connected to each other by the first conductor film.

2. A semiconductor device comprising:
a semiconductor substrate which has a main surface and has an element isolation region and first and second active regions which are arranged so as to be adjacent to the element isolation region in a first direction of the main surface;
an element isolation film made up from an insulation film formed on the main surface of the semiconductor substrate in the element isolation region;
a first gate insulation film formed on the main surface of the semiconductor substrate in the first active region;
a second gate insulation film formed on the main surface of the semiconductor substrate in the second active region;
a first silicon section which is formed on the first gate insulation film in the first active region and contains an impurity of a first conductivity type;
a second silicon section which is formed on the second gate insulation film in the second active region and contains an impurity of a second conductivity type which is an opposite conductivity type to the first conductivity type;
a third silicon section which is formed on the element isolation film in the element isolation region;
a first insulation film which is interposed between the first silicon section and the third silicon section;
a second insulation film which is interposed between the second silicon section and the third silicon section; and
a first conductor film which is continuously formed on each surface of the first silicon section, the second silicon section and the third silicon section,
wherein the first silicon section, the second silicon section and the third silicon section are electrically connected to each other by the first conductor film.

3. The semiconductor device according to claim 2,
wherein the first conductor film is made up from a silicide film.

4. The semiconductor device according to claim 3,
wherein, in a second direction orthogonal to the first direction, the first silicon section and the second silicon section have a first width as equal as each other.

5. The semiconductor device according to claim 4, further comprising:
a first semiconductor region and a second semiconductor region of the first conductivity type which are formed on both sides of the first silicon section in the first active region; and
a third semiconductor region and a fourth semiconductor region of the second conductivity type which are formed on both sides of the second silicon section in the second active region.

6. The semiconductor device according to claim 4,
wherein, in the second direction, a width of the third silicon section is the first width.

7. The semiconductor device according to claim 6,
wherein, in the second direction, the first insulation film and the second insulation film have the first width.

8. The semiconductor device according to claim 3, further comprising:
an interlayer insulation film which is formed on the first conductor film and has a first opening; and
a second conductor film which is formed in the first opening,
wherein the second conductor film is electrically connected to the first conductor film, and
the first opening is overlapped with the third silicon section when seen in a plan view.

9. The semiconductor device according to claim 2, further comprising:
a third insulation film which is formed between the third silicon section and the element isolation film; and
a fourth silicon section which is formed between the third insulation film and the element isolation film.

10. The semiconductor device according to claim 9,
wherein a film thickness of the fourth silicon section is smaller than a film thickness of the third silicon section.

11. A method of manufacturing a semiconductor device, comprising the steps of:
(a) preparing a semiconductor substrate which has a main surface and has an element isolation region and first and second active regions which are arranged so as to be adjacent to the element isolation region in a first direction of the main surface;
(b) forming an element isolation film made up from an insulation film on the main surface of the semiconductor substrate in the element isolation region;
(c) forming a first gate insulation film on the main surface of the semiconductor substrate in the first active region, and forming a second gate insulation film on the main surface of the semiconductor substrate in the second active region;
(d) forming a first silicon film on the first gate insulation film, the second gate insulation film and the element isolation film;
(e) in the element isolation region, forming a slit extending in a second direction orthogonal to the first direction in the first silicon film;
(f) forming a first insulation film on an inner wall of the slit;
(g) forming a second silicon film on the first insulation film so as to fill the slit;
(h) introducing an n-type impurity into the first silicon film in the second active region while using a first mask covering the first silicon film positioned in the first active region;
(i) introducing a p-type impurity into the first silicon film in the first active region while using a second mask covering the first silicon film positioned in the second active region; and
(j) applying a heat process to the semiconductor substrate.

12. The method of manufacturing the semiconductor device according to claim 11, further comprising the step of, after the step of (h) or the step of (i):
(k) forming a first silicon section which has a first width in the second direction and extends in the first direction on the first active region, a second silicon section which has the first width in the second direction and extends in the first direction on the second active region, and a third silicon section which has the first width in the second direction and extends in the first direction on the element isolation region by patterning the first silicon film and the second silicon film.

13. The method of manufacturing the semiconductor device according to claim 12, further comprising the step of, after the step of (k):
(l) forming a silicide film on surfaces of the first silicon section, the second silicon section and the third silicon section,
wherein the first silicon section, the second silicon section and the third silicon section are electrically connected to each other by the silicide film.

14. The method of manufacturing the semiconductor device according to claim 11, further comprising the step of, after the step of (g) but before the step of (h) and the step of (i):
(m) forming a first silicon section which has a first width in the second direction and extends in the first direction on the first active region, a second silicon section which has the first width in the second direction and extends in the first direction on the second active region, and a third silicon section which has the first width in the second direction and extends in the first direction on the element isolation region by patterning the first silicon film and the second silicon film.

15. The method of manufacturing the semiconductor device according to claim 14, further comprising the step of, after the step of (m):
(n) forming a silicide film on surfaces of the first silicon section, the second silicon section and the third silicon section,
wherein the first silicon section, the second silicon section and the third silicon section are electrically connected to each other by the silicide film.

16. The method of manufacturing the semiconductor device according to claim 15, further comprising the steps of:
forming an interlayer insulation film covering the silicide film;
forming an opening in the interlayer insulation film so as to be overlapped with the third silicon section when seen in a plan view;
forming a conductive film in the opening; and
forming a metallic wiring layer which is electrically connected to the conductive film, on the interlayer insulation film.

17. The method of manufacturing the semiconductor device according to claim 11,
wherein the slit in the step of (e) has a depth which reaches the element isolation film.

18. The method of manufacturing the semiconductor device according to claim 11,
wherein the first silicon film remains on the element isolation film after the step of (e), and the first insulation film is formed also on a bottom surface of the slit in the step of (f).
